(19) United States
(12) Patent Application Publication
(10) Pub. No.: US 2026/0187318 A1
(43) Pub. Date: Jul. 2, 2026

(54) SYSTEM, METHOD, AND PROGRAM PRODUCT FOR THE INVERSE DESIGN OF METAMATERIALS WITH PROGRAMMABLE NON-LINEAR FUNCTIONAL RESPONSES

(71) Applicant: The Regents of the University of California, Oakland, CA (US)

(72) Inventors: Xiaoyu Zheng, Berkeley, CA (US); Derek Qiang Xu, Poway, CA (US); Marco Maurizi, Berkeley, CA (US)

(21) Appl. No.: 19/420,356

(22) Filed: Dec. 15, 2025

Related U.S. Application Data
(60) Provisional application No. 63/739,471, filed on Dec. 27, 2024.

(51) Int. Cl. G06F 30/27; B33Y 70/00

(52) U.S. Cl. CPC G06F 30/27; B33Y 70/00

(57) ABSTRACT

A method for generating a metamaterial design based on a target physical response curve comprising a plurality of target physical response features including: pretraining, by imitation learning, a policy network, based on a first training set; fine-tuning, by reinforcement learning, the policy network, based on a second training set, predictions from a forward model, and a reward function; obtaining, by the policy network, the target physical response curve; generating, by a Monte Carlo tree search module (MCTS), a search tree, based on the target physical response curve and an upper confidence bound score (UCB); selecting, by MCTS, a graph representation of a metamaterial included in the terminal node with the highest reward.

### REFERENCE TO RELATED APPLICATION

This invention claims priority and the benefit of U.S. Provisional Patent Application Ser. No. 63/739,471, filed Dec. 27, 2024, and entitled “SYSTEM, METHOD, AND PROGRAM PRODUCT FOR THE INVERSE DESIGN OF METAMATERIALS WITH PROGRAMMABLE NON-LINEAR FUNCTIONAL RESPONSES,” the entire contents of which are hereby incorporated by reference.

### GOVERNMENT SUPPORT CLAUSE

This invention was made with government support under Grant Number N00014-23-1-2797 awarded by the Office of Naval Research. The government has certain rights in the invention.

### FIELD OF INVENTION

The present invention generally relates to a systems, methods, and program products for inverse design of metamaterials using machine learning. In embodiments, the invention generally relates to systems, methods, and program products for designing metamaterials with programmable nonlinear responses and geometric constraints in graph space.

### BACKGROUND OF THE INVENTION

Enabled by additive manufacturing, the architecture of metamaterials can be manipulated to achieve properties and functionalities beyond those of traditional engineering materials at a fraction of their weight [1-6]. Truss metamaterials—a class of low-density metamaterials—are composed of three-dimensional (3D) truss networks [7]. These new classes of materials proved to offer an extremely vast design and property space with unprecedented functionalities, from high stiffness-/strength-to-weight ratio [8][9] and tunable negative Poisson's ratio [10] to programmable elastic [11], piezoelectric anisotropy [1][12] and adaptive assembly and reconfigurability [13]-[15]. Large-deformation stress-strain and wave transmission responses are nonlinear material fingerprints, representing a material's behaviors to various stimuli, such as energy absorption and dissipation upon impact [16], large deformation upon activation [17], and vibration-borne noise modulation at different frequencies [18]. In truss materials, these nonlinear responses emerge from complex physics such as mechanical instabilities, frictional self-contact, and wave propagation. While exploring these broad design and property spaces is relatively simple using modern computational tools such as finite element (FE) method, automatically identifying a truss network's design for a given property or behavior—the so-called inverse design—remains challenging.

In the quest for inverse designing metamaterials, deep learning-driven approaches have demonstrated significant potential to efficiently optimize or inverse design specific, often linear, properties [10][19]-[32]. Despite their growing popularity in designing truss metamaterials [10], [19][22][24]-[26][29][30][32], existing methods face critical challenges: they require costly dataset collection, struggle to capture complex nonlinear behaviors, and fail to incorporate geometric and manufacturing constraints [33][34], all of which are crucial for engineering applications. Pixel- or voxel-based design methods, such as diffusion generative models [28][35], are inherently limited by the extremely high resolution needed to represent slender beams in 3D truss networks. When applied to inverse design 3D architected materials [35], these methods are poorly suited to truss networks. Furthermore, diffusion models demand large amounts of labeled training data, making them excessively costly for capturing nonlinear phenomena like frictional self-contact, mechanical instabilities, and wave propagation. For example, training a denoising diffusion model to inverse design nonlinear responses in two-dimensional, pixel-based structures requires approximately 50,000 labeled high-fidelity data points [28], rendering extension to 3D structures prohibitively expensive. These models also struggle to enforce geometric constraints due to their differentiable generative nature, frequently producing invalid, disconnected, or non-manufacturable structures. Approaches utilizing simple vector parameterizations, such as multilayer perceptron (MLP)-based tandem networks [36], are more data-efficient and do not require explicit enforcement of geometric constraints. However, their limited design space and expressive power restrict them to modifying existing designs, preventing generalization beyond the training data and resulting in limited response variability. Gradient-based optimization methods using MLP-driven generative models, such as variational autoencoders [37], partially address this by parametrizing truss materials as fixed-size graphs, significantly expanding the design space. Nevertheless, the lack of permutation invariance in MLPs—a fundamental property of graph data—and the generative nature of these models make them highly data-intensive, requiring hundreds of thousands of labeled samples. This bottleneck is especially pronounced when targeting nonlinear responses involving complex physics. While transfer learning can partially alleviate this issue, the fixed-size graph representation inherent to MLPs limits their ability to train across diverse graph-labeled datasets. Like voxel-based methods, these approaches also fail to incorporate geometric and manufacturing constraints, frequently resulting in disconnected or non-manufacturable designs.

What is needed is a system and method to inverse design and print metamaterials with programmable non-linear responses that address these and other technical challenges.

### BRIEF SUMMARY OF THE INVENTION

In view of the above, it is an object of the present invention to provide a method for generating a metamaterial design based on a target physical response curve comprising a plurality of target physical response features including: a. pretraining, by imitation learning, a policy network, based on a first training set, wherein: i. the first training set includes: a first plurality of graph representations of metamaterials, wherein a graph representation of a metamaterial includes nodes, edges, and graph connectivity; and a first plurality of physical response curve features associated with the first plurality of graph representations of metamaterials; ii. the policy network predicts a plurality of graph representations of metamaterials based on the first plurality of physical response curve features in the first training set; b. fine-tuning, by reinforcement learning, the policy network, based on a second training set, predictions from a forward model, and a reward function, wherein: i. the second training set includes a second plurality of physical response curve features; ii. the policy network is configured to predict a second plurality of graph representations of metamaterials based on the second plurality of physical response curve features in the second training set; iii, the forward model is configured to predict a third plurality of physical response curve features based on the second plurality of graph representations of metamaterials generated by the policy network; iv. the reward function is configured to generate a first reward based on the second plurality of physical response curve features in the second training set and the third plurality of physical response curve features generated by the forward model; and v. the fine-tuning continues until a predetermined first reward is met; c. obtaining, by the policy network, the target physical response curve; d. generating, by a Monte Carlo tree search module (MCTS), a search tree, based on the target physical response curve and an upper confidence bound score (UCB), wherein: i. the search tree is comprised of: a plurality of nodes, wherein a node of the search tree corresponds to a state sₖ, including a graph representation of a metamaterial and the target physical response curve; a plurality of connections, wherein a connection is between a pair of nodes, and a connection corresponds to an action aᵢ representing the difference between the graph representations of the pair of nodes; ii. the UCB is calculated for each connection in the plurality of connections based on: a reward score Q, calculated by the reward function, based on an average cumulative reward for selecting the connection in the search tree; a prediction, generated by the policy network, of the likelihood of selecting the connection from a plurality of connections connected to a first node in the pair of nodes, based on the target physical response curve; and the number of times the connection is selected by MCTS; iii. MCTS generates nodes based on connections that have a high UCB; and iv. the reward function generates a reward for each terminal node based on the target physical response curve features, and the graph representation of a metamaterial included in each terminal node; e. selecting, by MCTS, a graph representation of a metamaterial included in the terminal node with the highest reward.

In embodiments, the techniques described herein relate to a method, wherein the target physical response curve includes one or more of: a stress-strain response, an acoustic wave transmission response, a vibrational wave transmission response, or a photonic impedance profile.

In embodiments, the techniques described herein relate to a method, wherein the target physical response curve includes a stress-strain curve.

In embodiments, the techniques described herein relate to a method, wherein the target physical response curve includes a vibrational wave transmission response.

In embodiments, the techniques described herein relate to a method, wherein the vibrational wave transmission response is an acoustic wave transmission response.

In embodiments, the techniques described herein relate to a method, wherein the target physical response curve is non-linear.

In embodiments, the techniques described herein relate to a method, wherein the policy network further includes an action-stop decoder configured to accept one or more stop tokens.

In embodiments, the techniques described herein relate to a method, wherein the one or more stop tokens corresponds to: self-connectivity, cell-to-cell connectivity, printability, a maximum number of graph nodes, a maximum number of graph nodes per smallest representable volume of a graph, and relative density of connections.

In embodiments, the techniques described herein relate to a method, wherein a stop token corresponds to self-connectivity.

In embodiments, the techniques described herein relate to a method, wherein a stop token corresponds to printability.

In embodiments, the techniques described herein relate to a method, wherein a stop token corresponds to a maximum number of graph nodes.

In embodiments, the techniques described herein relate to a method, wherein a stop token corresponds to a maximum number of graph nodes per smallest representable volume of a graph.

In embodiments, the techniques described herein relate to a method, wherein a stop token corresponds to relative density of connections.

In embodiments, the techniques described herein relate to a method, wherein the first plurality of graph representation of metamaterials and the first plurality of physical response features are each 10,000 or less, 5,000 or less, or 3,000 or less.

In embodiments, the techniques described herein relate to a method, wherein the reward function is defined as: R=w_{J} J−w_{U}U, where J is a measure of the similarity between the target response y̅(x) and the generated metamaterial's response y(x), U is the uncertainty of the forward model, and w_{J} and w_{U} are two weighting hyperparameters.

In embodiments, the techniques described herein relate to a method, wherein the UCB is calculated as follows:

$$score ( {s}_{k} , {a}_{i} ) = Q ( {s}_{k} , {a}_{i} ) + {c}_{puct} \frac{π ( {s}_{k} , {a}_{i} )}{1 + N ( {s}_{k} , {a}_{i} )}$$

where the Q-score, Q(sₖ, aᵢ), is computed as the average cumulative reward obtained after selecting aᵢ from state sₖ throughout the search process, N(sₖ, aᵢ) is the number of times a particular action is selected, π(sₖ, aᵢ) is the predicted probability by the policy network, and c_{puct} is a hyperparameter controlling how much trust to place in the empirically computed reward across search and the trained policy network.

In embodiments, the techniques described herein relate to a method, wherein c_{puct} is set to 1-5, 2-3, or 2.5.

In embodiments, the techniques described herein relate to printing by a 3D printer, or causing printing by a 3D printer, the metamaterial based on the graph representation.

In exemplary embodiments the techniques described herein relate to a method for generating a metamaterial design based on a target physical response curve comprising a plurality of target physical response features including: a) obtaining, by a policy network, the target physical response curve; b) generating, by a Monte Carlo tree search module (MCTS), a search tree, based on the target physical response curve and an upper confidence bound score (UCB), wherein: i. the search tree is comprised of: 1. a plurality of nodes, wherein a node of the search tree corresponds to a state sₖ, including a graph representation of a metamaterial and the target physical response curve; 2. a plurality of connections, wherein a connection is between a pair of nodes, and a connection corresponds to an action aᵢ representing the difference between the graph representations of the pair of nodes; ii. the UCB is calculated for each connection in the plurality of connections based on: 1. a reward score Q, calculated by a reward function, based on an average cumulative reward for selecting the connection in the search tree; 2. a prediction, generated by the policy network, of the likelihood of selecting the connection from a plurality of connections connected to a first node in the pair of nodes, based on the target physical response curve; and 3. the number of times the connection is selected by MCTS; iii. MCTS generates nodes based on connections that have a high UCB; and iv. the reward function generates a reward for each terminal node based on the target physical response curve features, and the graph representation of a metamaterial included in each terminal node; c) selecting, by MCTS, a graph representation of a metamaterial included in the terminal node with the highest reward.

In embodiments, the techniques described herein relate to a method, wherein the target physical response curve includes one or more of: a stress-strain response, an acoustic wave transmission response, a vibrational wave transmission response, or a photonic impedance profile.

In embodiments, the techniques described herein relate to a method, wherein the target physical response curve includes a stress-strain curve.

In embodiments, the techniques described herein relate to a method, wherein the target physical response curve includes a vibrational wave transmission response.

In embodiments, the techniques described herein relate to a method, wherein the vibrational wave transmission response is an acoustic wave transmission response.

In embodiments, the techniques described herein relate to a method, wherein the target physical response curve is non-linear.

In embodiments, the techniques described herein relate to a method, wherein the policy network further includes an action-stop decoder configured to accept one or more stop tokens.

In embodiments, the techniques described herein relate to a method, wherein the one or more stop tokens corresponds to: self-connectivity, cell-to-cell connectivity, printability, a maximum number of graph nodes, a maximum number of graph nodes per smallest representable volume of a graph, and relative density of connections.

In embodiments, the techniques described herein relate to a method, wherein a stop token corresponds to self-connectivity.

In embodiments, the techniques described herein relate to a method, wherein a stop token corresponds to printability.

In embodiments, the techniques described herein relate to a method, wherein a stop token corresponds to a maximum number of graph nodes.

In embodiments, the techniques described herein relate to a method, wherein a stop token corresponds to a maximum number of graph nodes per smallest representable volume of a graph.

In embodiments, the techniques described herein relate to a method, wherein a stop token corresponds to relative density of connections.

In embodiments, the techniques described herein relate to a method, wherein the first plurality of graph representation of metamaterials and the first plurality of physical response features are each 10,000 or less, 5,000 or less, or 3,000 or less.

In embodiments, wherein the reward function is defined as: R=w_{J}J−w_{U}U, where J is a measure of the similarity between the target response y̅(x) and the generated metamaterial's response y(x), U is the uncertainty of the forward model, and w_{J} and w_{U} are two weighting hyperparameters.

In embodiments, the techniques described herein relate to a method, wherein the UCB is calculated as follows:

$$score ( {s}_{k} , {a}_{i} ) = Q ( {s}_{k} , {a}_{i} ) + {c}_{puct} \frac{π ( {s}_{k} , {a}_{i} )}{1 + N ( {s}_{k} , {a}_{i} )}$$

where the Q-score, Q(sₖ, aᵢ), is computed as the average cumulative reward obtained after selecting aᵢ from state sₖ throughout the search process, N(sₖ, aᵢ) is the number of times a particular action is selected, π(sₖ, aᵢ) is the predicted probability by the policy network, and c_{puct} is a hyperparameter controlling how much trust to place in the empirically computed reward across search and the trained policy network.

In embodiments, the techniques described herein relate to a method, wherein c_{puct} is set to 1-5, 2-3, or 2.5.

In embodiments, the techniques described herein relate to a computer system for generating a metamaterial design including one or more processors operably connected to one or more memories, the one or more memories containing computer-readable instructions, then when executed, cause the one or more processors to perform a method for designing metamaterials based on a target physical response curve comprising a plurality of target physical response features including: a. pretraining, by imitation learning, a policy network, based on a first training set, wherein: i. the first training set includes: a first plurality of graph representations of metamaterials, wherein a graph representation of a metamaterial includes nodes, edges, and graph connectivity; and a first plurality of physical response curve features associated with the first plurality of graph representations of metamaterials; ii. the policy network predicts a plurality of graph representations of metamaterials based on the first plurality of physical response curve features in the first training set; b. fine-tuning, by reinforcement learning, the policy network, based on a second training set, predictions from a forward model, and a reward function, wherein: i. the second training set includes a second plurality of physical response curve features; ii. the policy network is configured to predict a second plurality of graph representations of metamaterials based on the second plurality of physical response curve features in the second training set; iii, the forward model is configured to predict a third plurality of physical response curve features based on the second plurality of graph representations of metamaterials generated by the policy network; iv. the reward function is configured to generate a first reward based on the second plurality of physical response curve features in the second training set and the third plurality of physical response curve features generated by the forward model; and v. the fine-tuning continues until a predetermined first reward is met; c. obtaining, by the policy network, the target physical response curve; d. generating, by a Monte Carlo tree search module (MCTS), a search tree, based on the target physical response curve and an upper confidence bound score (UCB), wherein: i. the search tree is comprised of: a plurality of nodes, wherein a node of the search tree corresponds to a state sₖ, including a graph representation of a metamaterial and the target physical response curve; a plurality of connections, wherein a connection is between a pair of nodes, and a connection corresponds to an action aᵢ representing the difference between the graph representations of the pair of nodes; ii. the UCB is calculated for each connection in the plurality of connections based on: a reward score Q, calculated by the reward function, based on an average cumulative reward for selecting the connection in the search tree; a prediction, generated by the policy network, of the likelihood of selecting the connection from a plurality of connections connected to a first node in the pair of nodes, based on the target physical response curve; and the number of times the connection is selected by MCTS; iii. MCTS generates nodes based on connections that have a high UCB; and iv. the reward function generates a reward for each terminal node based on the target physical response curve features, and the graph representation of a metamaterial included in each terminal node; e. selecting, by MCTS, a graph representation of a metamaterial included in the terminal node with the highest reward.

In embodiments, the techniques described herein relate to a first plurality of graph representations of metamaterials, wherein a graph representation of a metamaterial includes nodes, edges, and graph connectivity; and

In embodiments, the techniques described herein relate to a method, wherein the target physical response curve includes one or more of: a stress-strain response, an acoustic wave transmission response, a vibrational wave transmission response, or a photonic impedance profile.

In embodiments, the techniques described herein relate to a method, wherein the target physical response curve includes a stress-strain curve.

In embodiments, the techniques described herein relate to a method, wherein the target physical response curve includes a vibrational wave transmission response.

In embodiments, the techniques described herein relate to a method, wherein the vibrational wave transmission response is an acoustic wave transmission response.

In embodiments, the techniques described herein relate to a method, wherein the target physical response curve is non-linear.

In embodiments, the techniques described herein relate to a method, wherein the policy network further includes an action-stop decoder configured to accept one or more stop tokens.

In embodiments, the techniques described herein relate to a method, wherein the one or more stop tokens corresponds to: self-connectivity, cell-to-cell connectivity, printability, a maximum number of graph nodes, a maximum number of graph nodes per smallest representable volume of a graph, and relative density of connections.

In embodiments, the techniques described herein relate to a method, wherein a stop token corresponds to self-connectivity.

In embodiments, the techniques described herein relate to a method, wherein a stop token corresponds to printability.

In embodiments, the techniques described herein relate to a method, wherein a stop token corresponds to a maximum number of graph nodes.

In embodiments, the techniques described herein relate to a method, wherein a stop token corresponds to a maximum number of graph nodes per smallest representable volume of a graph.

In embodiments, the techniques described herein relate to a method, wherein a stop token corresponds to relative density of connections.

In embodiments, the techniques described herein relate to a method, wherein the first plurality of graph representation of metamaterials and the first plurality of physical response features are each 10,000 or less, 5,000 or less, or 3,000 or less.

In embodiments, wherein the reward function is defined as: R=w_{J}J−w_{U}U, where J is a measure of the similarity between the target response y̅(x) and the generated metamaterial's response y(x), U is the uncertainty of the forward model, and w_{J} and w_{U} are two weighting hyperparameters.
the techniques described herein relate to a method, wherein the UCB is calculated as follows:

$$score ( {s}_{k} , {a}_{i} ) = Q ( {s}_{k} , {a}_{i} ) + {c}_{puct} \frac{π ( {s}_{k} , {a}_{i} )}{1 + N ( {s}_{k} , {a}_{i} )}$$

where the Q-score, Q(sₖ, aᵢ), is computed as the average cumulative reward obtained after selecting aᵢ from state sₖ throughout the search process, N(sₖ, aᵢ) is the number of times a particular action is selected, π(sₖ, aᵢ) is the predicted probability by the policy network, and c_{puct} is a hyperparameter controlling how much trust to place in the empirically computed reward across search and the trained policy network.

In embodiments, the techniques described herein relate to a method, wherein c_{puct} is set to 1-5, 2-3, or 2.5.

### BRIEF DESCRIPTION OF THE DRAWINGS

The above and related objects, features and advantages of the present disclosure will be more fully understood by reference to the following detailed description of the preferred, albeit illustrative, embodiments of the present invention when taken in conjunction with the accompany figures, wherein:

FIG. 1A depicts a representative periodic truss metamaterial sampled from a test design space in accordance with embodiments of the present invention;

FIG. 1B depicts a graph representation of metamaterials in accordance with embodiments of the present invention;

FIG. 1C depicts the generation of graphs with cubic symmetry to form datasets in accordance with embodiments of the present invention;

FIG. 1D depicts examples of cubic symmetric graphs generated by the methods described in FIG. 1C, in accordance with embodiments of the present invention;

FIG. 1E depicts the stress-strain dimensionless curve space with seven highlighted representative examples extracted from the generated dataset and gray curves in the background, in accordance with embodiments of the present invention;

FIG. 1F depicts the vibration transmission dimensionless curve space with six highlighted representative examples extracted from the generated dataset and gray curves in the background, in accordance with embodiments of the present invention;

FIG. 2A depicts an autoregressive policy network used to generate graphical representations of metamaterial with target functional responses, in accordance with embodiments of the present invention;

FIG. 2B depicts geometric and manufacturing constraints that can be enforced in embodiment of the present invention;

FIG. 2C depicts examples of inverse designed unit cells with and without printability constraints, for a target stress-strain response curve, in accordance with embodiments of the present invention;

FIG. 2D depicts a generated unit cell graph, finally converted into a CAD model, tessellated periodically in space, 3D-printed using digital light stereolithography, and experimentally tested using universal testing machines or electrodynamical shakers along with laser vibrometers, in accordance with embodiments of the present invention;

FIG. 3A depicts target curves sampled from the ‘known curve space’ (test dataset) in accordance with embodiments of the present invention;

FIG. 3B depicts target curves sampled from the ‘unknown curve space’ (user-defined targets), in accordance with embodiments of the present invention;

FIG. 4A depicts target curves sampled from the ‘known curve space’ (test dataset) in accordance with embodiments of the present invention;

FIG. 4B depicts target binary sequences sampled from the ‘unknown curve space’ (user-defined targets) in accordance with embodiments of the present invention;

FIG. 5A depicts a representative target stress-strain curve for cushioning application;

FIG. 5B depicts schematic model of a chest protector, highlighting foams from a commercial lacrosse chest protector and the generated and 3D-printed metamaterial design in accordance with embodiments of the present invention;

FIG. 5C depicts an experimental stress-strain curves of the GMM generated design compared with those of the protector's foams (‘Foams’), Kelvin foam, and octet structure, in accordance with embodiments of the present invention;

FIG. 5D depicts a summary plot of energy absorption, U vs. peak stress, σₘₐₓ for all experiments in accordance with embodiments of the present invention;

FIG. 5E depicts a frequency vs. design plot, highlighting GMM's ability to design a large diversity of tunable attenuation gaps in the frequency range 1-12 kHz, in accordance with embodiments of the present invention;

FIG. 5F depicts a generated unit cell graph along with the corresponding measured transmission response with small attenuation gap at higher frequencies, in accordance with embodiments of the present invention;

FIG. 5G depicts a generated unit cell graph along with the corresponding measured transmission response with two large attenuation gaps at lower and higher frequencies, in accordance with embodiments of the present invention;

FIG. 5H depicts a generated design with broadband attenuation gap in the whole frequency range, with potential applications to vibration-damping panels in EVs, in accordance with embodiments of the present invention;

FIG. 6 shows a schematic of a forward model's architecture, in accordance with embodiments of the present invention;

FIG. 7A depicts predicted vs. true graph node coordinates of the VAE generated metamaterials based on a test set;

FIG. 7B depicts predicted vs. true relative density of the VAE generated metamaterials based on a test set;

FIG. 7C depicts predicted vs. true normalized stress values of the VAE generated metamaterials based on a test set;

FIG. 7D depicts four randomly extracted test vs. VAE-reconstructed graphs;

FIG. 7E depicts predicted vs. true stress-strain curves of the corresponding structures in FIG. 7D;

FIG. 8A depicts benchmarking GraphMetaMat with the MLP-based tandem-network model of ref. [36] on the target curves in FIG. 3A;

FIG. 8B depicts benchmarking GraphMetaMat with the MLP-based tandem-network model of ref. [36] on the target curves in FIG. 3B;

FIG. 9A depicts relative error distributions for stress-strain inverse design on the test dataset;

FIG. 9B depicts inference results on the target curves in FIG. 3;

FIG. 9C depicts diffusion-generated structures for the first 25 target test stress-strain curves;

FIGS. 10A-10B depict benchmark summaries between GraphMetaMat and state-of-the-art inverse-design methods;

FIG. 11 depicts a process flow diagram according to embodiments of the present invention.

### DETAILED DESCRIPTION OF THE INVENTION

The present invention generally relates to a systems, methods, and program products for inverse design of metamaterials using machine learning. In embodiments, the invention generally relates to systems, methods, and program products for designing metamaterials with programmable nonlinear responses and geometric constraints in graph space.

The present invention relates to systems and methods for the inverse design of three-dimensional metamaterials.

The present invention addresses the challenges mentioned above. Embodiments in accordance with present invention include, GraphMetaMat (GMM), a graph-based framework that uses a graph neural network (GNN) agent to perform autoregressive metamaterial generation. In embodiments, the GNN generates the metamaterial structure autoregressively, advancing one step at a time. In embodiments, the GNN autoregressively generates two steps at a time.

In embodiments in accordance with the present invention, a ‘response-to-structure’ policy network, combined with a ‘structure-to-response’ surrogate model and Monte Carlo tree search (MCTS), is trained via deep imitation learning (IL) and reinforcement learning (RL), to inverse design truss metamaterials with prescribed nonlinear functional responses and arbitrary geometric constraints. In embodiments the surrogate model is replaced with finite element analysis.

In embodiments, the invention can inverse design metamaterials for compressive stress-strain and vibration transmission curves, originating from complex nonlinear material behavior such as buckling, large deformations, frictional contact, wave propagation and damping.

Embodiments can rapidly generate metamaterial designs with nonlinear stress responses spanning four orders of magnitude up to 30% of strain and wave transmission curves with tunable attenuation gaps (i.e., low transmission values) in the frequency range 1-12 kHz. Embodiments of the present invention can discover lightweight metamaterials that can be readily printed, with high energy absorption yet low peak stress and with low vibration transmission, potentially suitable for protective equipment and noise-reduction panels in electric vehicles. Embodiments of the present invention provide a tool to navigate the vast design space enabled by architected materials and additive manufacturing, allowing for fully automated discovery and design of manufacturable metamaterials.

### Overview of Methods

FIG. 11 depicts a process flow diagram in accordance with embodiments of the present invention. In embodiments, methods according to the present invention include one or more of pretraining, by imitation learning, a policy network, based on a first training set (S1100), fine-tuning, by reinforcement learning, the policy network, based on a second training set, predictions from a forward model, and a reward function (S1102), obtaining, by the policy network, the target physical response curve (S1104), generating, by a Monte Carlo tree search module (MCTS), a search tree, based on the target physical response curve and an upper confidence bound score (UCB) (S1106), and selecting, by MCTS, a graph representation of a metamaterial included in the terminal node with the highest reward (S1108).

In embodiments, the methods further include printing by a 3D printer, or causing printing by a 3D printer, the metamaterial based on the graph representation.

### Computer Implemented Methods

In embodiments, the methods described herein are performed, in whole or in part, by a computer system. In embodiments, the computer system includes one or more processors operatively coupled to memory storing instructions that, when executed by the processors, cause the computer system to carry out the steps of the method. In embodiments, the method is implemented using hardware, software, firmware, or any combination thereof. In embodiments, the computer system includes input and output interfaces configured to receive data, execute the computational steps recited herein, and generate corresponding output. In embodiments, the computer system executes the method automatically, semi-automatically, or under user control. In embodiments, the computer system further includes network communication components configured to transmit, receive, or process data used in the method. In embodiments, the method steps can be distributed across multiple computing devices or executed on a single device. In embodiments, the computer-implemented aspects of the method reside on a non-transitory computer-readable medium storing instructions for performing the method.

### Graph-Response Space

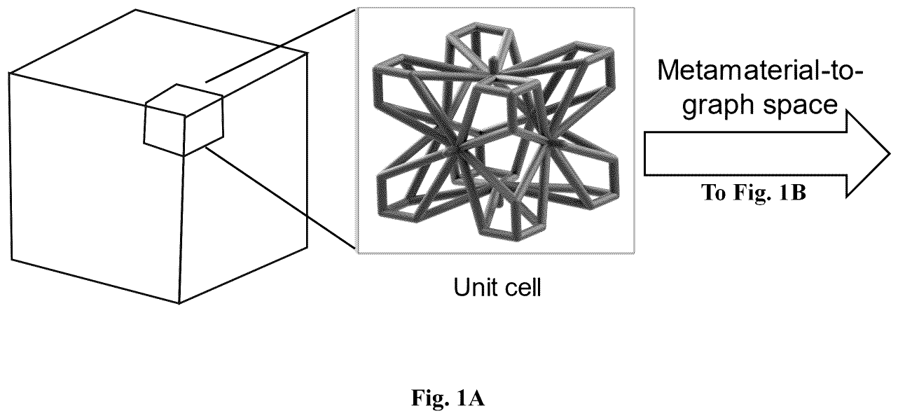

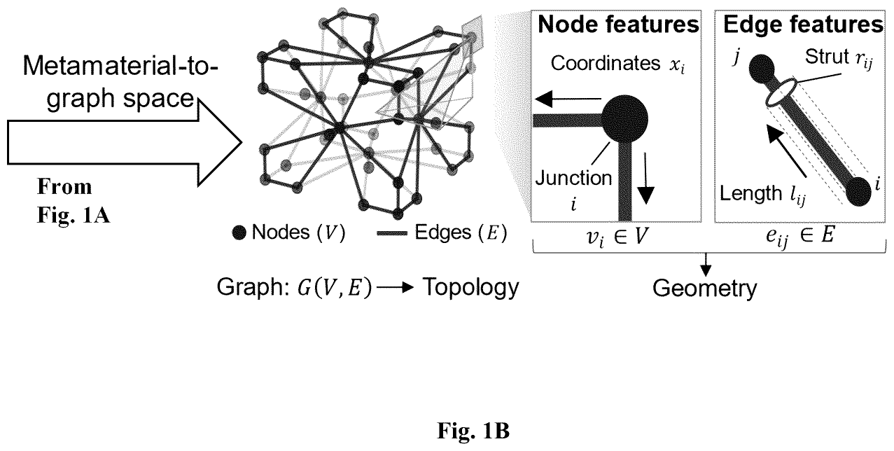

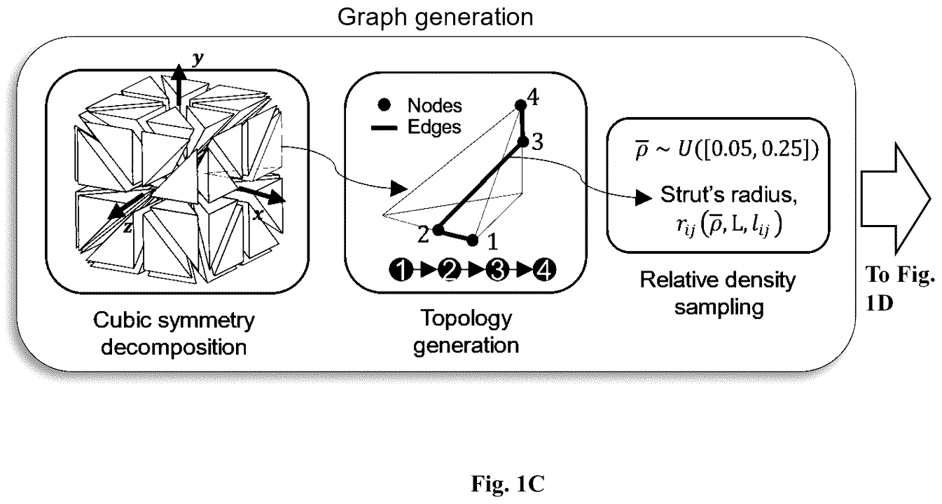

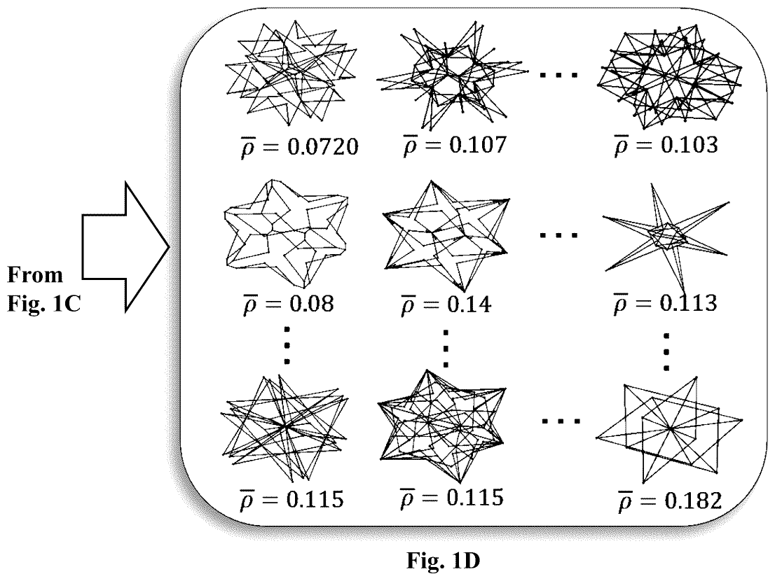

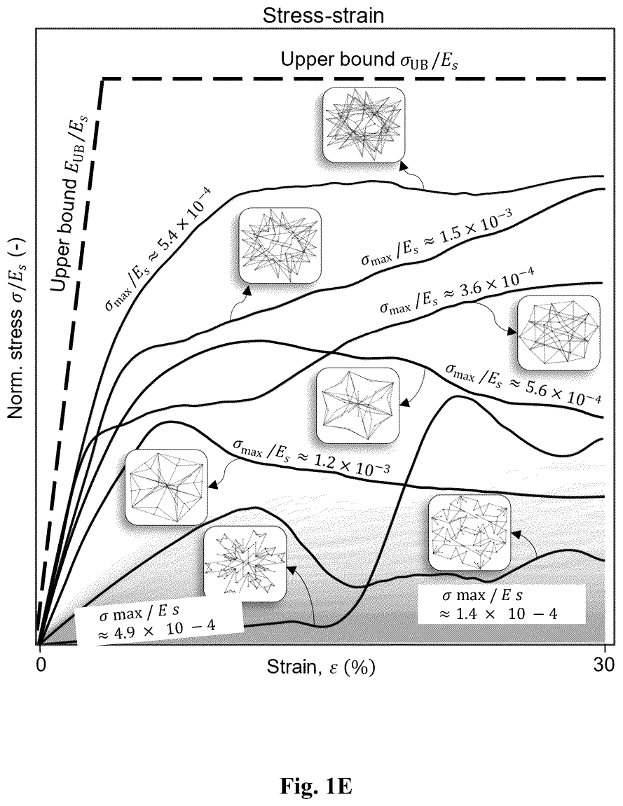

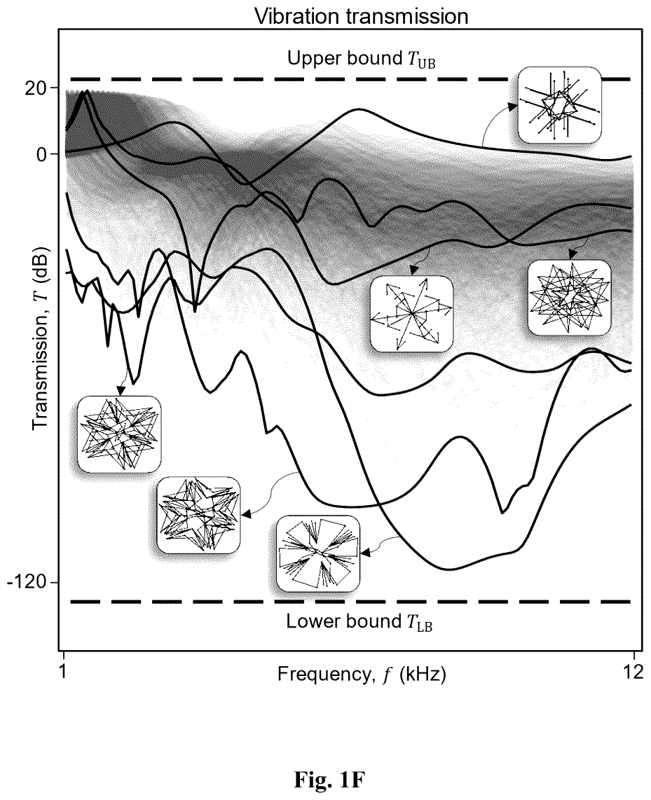

FIG. 1A depicts a representative periodic truss metamaterial sampled from a test design space in accordance with embodiments of the present invention. In embodiments, the metamaterials are made up of a number of repeating unit cells, also referred to as unit cells. In embodiments, the metamaterials are periodic truss metamaterial. Periodic truss metamaterials are arranged in a periodic, repeating truss-like lattice.

In embodiments the repeating cell units are of one type, forming a homogenous metamaterial. In embodiments, the cell units are of different types, forming a heterogenous metamaterial.

FIG. 1B depicts a graph representation of metamaterials in accordance with embodiments of the present invention. FIG. 1B, shows the graphical encoding of an exemplary unit cell of a periodic truss metamaterial displayed in FIG. 1A. In embodiments, metamaterials are graphically encoded using vertices (also known as nodes), and edges. In embodiments, metamaterials are graphically encoded using vertices, edges, and relative density of connections. In the embodiments of FIG. 1B, a graphical representation is represented as G (V, E), with V a collection of nodes connected through edges E, of the metamaterial's unit cell in FIG. 1A. Node vᵢ and edge eᵢⱼ features used to encode geometric information are shown in FIG. 1B. In embodiments, topological information is encoded as inductive bias into the graph connectivity by construction.

As shown in FIG. 1B, the nodes and edges can contain features. In embodiments, the node features include one or both of coordinates xᵢ and junction j. In embodiments, the edge features include one or more of length lᵢⱼ, strut radius, rᵢⱼ, and the nodes between which the edge is located, j and i.

FIG. 1C depicts the generation of graphs with cubic symmetry to form datasets in accordance with embodiments of the present invention. In embodiments, the datasets may be used as a first training set or a second training dataset. In embodiments, a dataset may be used to train one or more of a policy network or a forward model.

As show in the first panel of FIG. 1C, in embodiments where a cubic symmetric metamaterial is used, the cubic symmetric metamaterial can be decomposed based on symmetry. In embodiments, other symmetric metamaterial may be used, such as rectangular metamaterial, or triangular prism metamaterial, to name a few examples. In embodiments where a symmetric metamaterial is used, the symmetric metamaterial may be symmetrically decomposed.

As show in the second panel of FIG. 1C, in embodiments, smallest representable volume (SRV) graphs are generated by placing nodes along the edges of the SRV and connecting them to form a sequence. This method ensures self-connectivity and cell-to-cell connectivity.

Random node placement and sequence connection allow to create a large pool of diverse graphs to create a dataset.

As shown in the third panel of FIG. 1C, relative density, ρ̅ may be obtained by randomly sampling from a uniform distribution U(ρ̅), in the range [0.05, 0.25], in accordance with embodiments of the present invention. In embodiments, relative density may be obtained via other methods such as non-random sampling, or larger ranges of a uniform distribution, or a non-uniform distribution, to name a few examples. In embodiments, the strut radius, rᵢⱼ is accordingly obtained by

$${r}_{i j} ( \overline{ρ} , L , {l}_{i j} ) = \sqrt{\overline{ρ} \frac{{L}^{3}}{π {\sum }_{i , j}^{N} {l}_{i j}}} ,$$

where L is the unit cell size, lᵢⱼ is the strut length between node i and j, and N is the number of struts.

FIG. 1D depicts examples of cubic symmetric graphs generated by the methods described in FIG. 1C, in accordance with embodiments of the present invention. A randomly sampled relative density ρ̅ is assigned to each randomly generated graph.

FIG. 1E depicts the stress-strain dimensionless curve space with seven highlighted representative examples extracted from the generated dataset and gray curves in the background, in accordance with embodiments of the present invention. The stress is normalized by the constitutive material's Young's modulus Eₛ. The curves are rescaled for illustration purposes. The normalized peak stress is thus reported on top of each curve. The stiffness and strength upper bounds, computed using the Voight bounds (rule of mixtures), delimit the design region.

FIG. 1F depicts the vibration transmission dimensionless curve space with six highlighted representative examples extracted from the generated dataset and gray curves in the background, in accordance with embodiments of the present invention.

Translating truss metamaterials into graphs allows exploitation of the inductive biases of GNNs [38]. In ‘graph space’ (FIGS. FIGS. 1A-1B), metamaterial struts and junctions (intersections between struts) are represented as edges (E) and nodes (V) of the graph G (V, E), respectively. The geometry, including node coordinates, xᵢ and strut length, lᵢⱼ, is encoded into node (vᵢ) and edge (eᵢⱼ) features, for each node i, j. In embodiments, uniform relative density, ρ̅ is assumed across the metamaterial. Hence, ρ̅ is not directly encoded through GNNs, but processed via MLPs and concatenated with graph embeddings, if needed. The topology of the metamaterial, i.e., which struts connect to each other, is captured by the graph connectivity, eliminating the need to parametrize the design space with pre-existing structures [30][36][39] or pre-selected building blocks [29][40]. In embodiments, uniform relative density is not assumed. In embodiments, pre-existing structures and pre-existing building blocks are parameterized into the design space.

In embodiments, the design space can be restricted to cubic symmetric periodic truss metamaterials with cylindrical struts (FIG. 1C). This is similar to ref. [41]. In this design space, a cubic volume is decomposed into 48 tetrahedra, representing the ‘smallest representative volumes’ (SRVs). The corresponding graph is constructed in the SRV by placing nodes along its edges and connecting them to form a sequence (FIG. 1C). The struts' radius, rᵢⱼ is then obtained from the relative density, ρ̅ sampled in the range 0.05-0.25, assuming a constant unit cell size, L. In embodiments, the relative density is sampled in the range of 0.1-0.2. In embodiments, the cubic volume is decomposed into 24 tetrahedra, or 64 tetrahedra.

By varying nodes, node coordinates, connectivity, and relative density, a large pool of diverse designs can be generated (FIG. 1D). While embodiments use the design space of cubic symmetric periodic truss metamaterials with cylindrical struts, any 3D truss architecture, made of any constitutive material, can be represented using graphs, without limitations to regular periodic [37][42][43] or two-dimensional structures [29][32][44]. Cubic symmetry ensures invariant mechanical properties along three orthogonal directions and facilitates the generation of heterogeneous metamaterials by modifying only the interior nodes and connectivity, thus avoiding boundary node-matching methods [40]. Moreover, this design space also includes classical stretching- and bending-dominated lattices, such as octet and Kelvin foams, as well as bi-stable structures.

This potentially unlimited design space, while challenging, offers the opportunity to design metamaterials with a wide variety of functional responses. In embodiments, a first training set or a second training set can be created by collected by randomly generating 1,000-10,000 graphs, preferably 2,000-5,000, preferably 3,000 graphs. After the graphs have been generated, physical response curve features can be predicted yielding a dataset including graphical representations of metamaterials and associated physical response curve features. In embodiments, physical response curve features can be obtained via high-fidelity finite element (FE) simulations, analytical methods, or physics informed neural networks to name a few examples. In embodiments, the physical response curve is a target physical response, for which a metamaterial can be generated in accordance with embodiments of the present invention. In embodiments, the target physical response curve is comprised of target physical response curve features. The target physical response curve features may be any type of embedding of the target physical response, such as a discretization of the target physical response curve into target physical response points, in embodiments, 64, 128, or 256 such points to name a few examples.

Each graph represents a metamaterial with varying geometry, topology, and relative density. FIGS. 1E and 1F show the corresponding dimensionless curve spaces, which delimit the design regions for embodiments of the present invention by upper and lower bounds, and a few representative curves and graphs from datasets in accordance with embodiments.

In embodiments, the metamaterials are comprised of a single linear elastic constitutive material. In such embodiments, multiple types of compressive responses, including strain hardening and softening, across four orders of magnitude, emerge from the combination of large deformations, buckling, and frictional contact.

In embodiments, metamaterials with vibration transmission curves with complex features and variable attenuation gaps, spanning the range −120-20 dB, can be designed. In these embodiments, the vibration transmission curves arise from the interplay between architecture and relative density. This vast design space enables the framework of the present invention to inverse design target functional responses, spanning orders of magnitude in stress and featuring complex transmission characteristics.

In embodiments, the metamaterials are comprised of one or more of the following: multiple distinct materials, non-elastic materials, or non-linear elastic materials.

### Forward Model

In embodiments, the present invention includes a forward model. In embodiments, the forward model is used in one or more of reinforcement learning and Monte Carlo tree search. In embodiments, the forward model comprises one or more of a graph encoder, a magnitude decoder, a density encoder and a shaper decoder.

Serving as surrogate model for computational complex methods like FE, the forward model takes as input the graph representation G of the metamaterial and predicts the corresponding functional response y(x), where x is the independent variable (either strain & or frequency f in our case). Specifically, the inputs of the model are node coordinates and struts' length, encoded as graph node vᵢ∈V and edge eᵢⱼ∈E features, for i, j=1, . . . , N, respectively, with N the number of nodes of the graph G. In embodiments, constant strut radius is assumed. Under the assumption of constant struts' radius, relative density ρ̅ is passed to the model without encoding it into graph features. The outputs, in general, can be decomposed into y(x)=yₘₐₓ yₛₕₐₚₑ (x), where yₘₐₓ is the maximum of the curve, here called magnitude, and yₛₕₐₚₑ is the normalized response with unitary maximum. In embodiments, this decomposition is here exploited in the stress-strain response prediction, where yₘₐₓ and yₛₕₐₚₑ (x) are predicted separately by two output network's branches. Instead, the wave transmission response is entirely predicted as a unique vector y(x), simply by turning off the magnitude branch. The vector size is (1, L), with L the resolution.

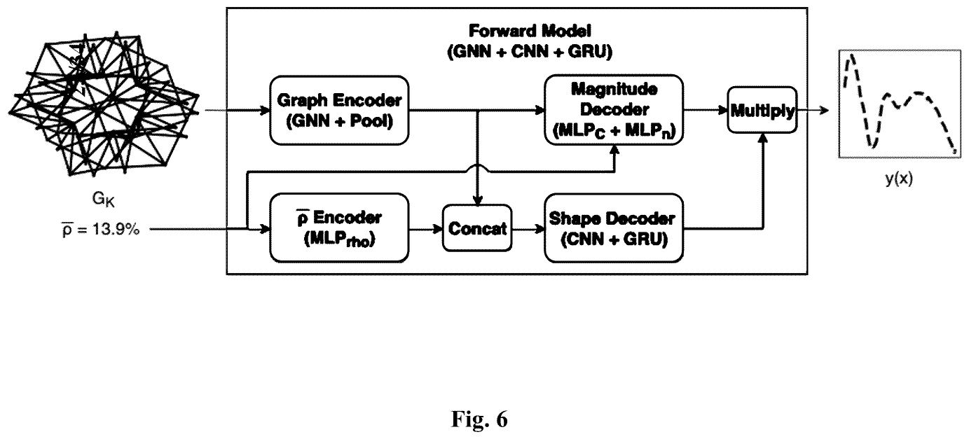

FIG. 6 depicts a schematic of a forward model's architecture, in accordance with embodiments of the present invention. In embodiments, the model first up-projects node and edge features using a linear layer. In embodiments, it then encodes the graph into an embedded latent vector via a message passing neural network (MPNN) and a pooling layer. In embodiments, from this embedded representation, two decoders, the magnitude decoder and shape decoder, output yₘₐₓ and yₛₕₐₚₑ (x), respectively. In embodiments, the magnitude decoder is only active for stress-strain responses. In embodiments, the peak stress is constrained to follow

$${y}_{max} = C {\overline{ρ}}^{n} ,$$

with C and n two functions of geometry and topology of the structure, predicted by two distinct multilayer perceptrons (MLPs). In embodiments, this inductive bias is injected by predicting log(yₘₐₓ)=log(C)+n log(ρ̅). In embodiments, the shape decoder is active for both functional responses. In embodiments, the graph embedding is first up-sampled by a transposed convolutional network (CNN). In embodiments, a gated recurrent unit (GRU) and a linear readout layer process and output the final functional response, respectively. Only variation to the model architecture is made for stress-strain curve prediction. To inject the inductive bias accounting for the dependence of the curve' shape on ρ̅, the graph embedding is initially concatenated to the embedding of ρ̅, obtained by an MLP.

In embodiments, the forward model is a graphical neural network (GNN). In embodiments, the forward model is pre-trained and fine-tuned. In embodiments, The GNN was pretrained on a publicly available unlabeled dataset (i.e., no associated functional responses). Although this dataset was constructed using a different parametrization, in embodiments, the forward model can deal with any graph representation. In embodiments, the model is constructed by adding a linear decoder after the GNN and pooling layers, mapping graph representations to the corresponding stiffness matrix coefficients (such as 22 scalar values). In embodiments, this model was trained for 100 epochs using an AdamW optimizer with a learning rate of 0.001 and a weight decay of 0.01. In embodiments, during fine-tuning on a labeled dataset, the linear decoder can be replaced with shape and magnitude decoders, which were randomly initialized. Any of these parameters may be modified according to embodiments of the present invention.

### Inverse Model Training

In embodiments, the inverse model training protocol consists of one of more of imitation learning and reinforcement learning. In embodiments, the inverse model training protocol consists of two stages: imitation learning (IL) and reinforcement learning. In embodiments, the goal of IL is to leverage existing graph-labeled training curves. In embodiments, the goal of RL is to tailor the policy network to unlabeled responses. In embodiments, batch size is set to 128.

In embodiments, 64 epochs of IL are run using the AdamW optimizer with a learning rate of 0.001 and eps of 10⁻⁸ on the same 90:5:5 split dataset, as the forward model training protocol. In these embodiments, the input is now the ground-truth response. In these embodiments, the output is the unit cell graph \tilde{G}, now treated as label. These sequences are constructed by first extracting the SRV graph, \tilde{G}_{K} from the metamaterial's unit cell. In embodiments, a Breadth-First Search (BFS) algorithm is run starting from the highest degree node in \tilde{G}_{K}, recording the sequence of edges: [(u₁, v₁), (u₂, v₂), . . . , (u_{K}, v_{K})]: (uᵢ, vᵢ)∈\tilde{G}ₖ. BFS ensures every edge in the sequence is connected to a node in one of the previously seen edges. The sequence of edges is ended with the stop token. In embodiments, during IL, the policy network is first trained to reproduce the edge sequences given the input response with maximum likelihood.

In embodiments, 1024 iterations of RL are run using the Adam optimizer with learning rate of 0.001 and eps of 0.001 on the (unlabeled) target responses. In embodiments, the RL algorithm optimizes the agent to generate graphs with the desired response by first trying different actions, then encouraging the policy network to pick actions that produce higher reward.

In embodiments, the reward function is defined as R=w_{J}J−w_{U}U, where J is a measure of the similarity between the target response y̅(x) and the generated metamaterial's response y(x), U is the uncertainty of the forward model, and w_{J} and w_{U} are two weighting hyperparameters. R may be referred to as a reward score. In embodiments, this reward is applied to the final action, and intermediary actions have no reward. In embodiments using RL, because RL requires repeated reward computation, the trained forward model was used to efficiently predict the response of the inverse-designed metamaterials.

In embodiments, the Proximal Policy Optimization (PPO) framework [19] is adopted. In embodiments, for every 8 iterations, 1 training iteration was run. To improve training stability, the advantages were normalized by the mean and standard deviation. In embodiments, the value estimate as the mean value derived from historical state-action-reward pairs. In embodiments, to balance exploitation and exploration, the entropy coefficient was set to 0.0001. In embodiments, the gradient clipping was set to 0.01. In embodiments, to improve training stability, the clipping coefficient in the PPO loss function was set to 0.15, and the reward clipping (after normalization) between −1.0 and 1.0. Any of these parameters may be modified according to embodiments of the present invention.

### Monte Carlo Tree Search (MCTS)

In embodiments, the present invention employs a Monte-Carlo Tree Search (MCTS) graphical search algorithm. In embodiments, the MCTS algorithm is included in an MCTS module, which includes the MCTS algorithm, and optionally includes other software. In embodiments, the MCTS module is operatively connected to a policy network.

To fully leverage the autoregressive nature of the inverse model, embodiments according to the present invention leverage more powerful search algorithms than greedy decoding to perform inference. MCTS searches through multiple action sequences by repeatedly sampling actions from the initial state. MCTS balances exploitation and exploration by prioritizing actions that the policy network assigns high probability to and actions that had not been previously explored. In embodiments, MCTS does this through the Upper Confidence Bound (UCB) score, where the score of the action aᵢ, score (aᵢ), is computed as:

$$score ( {s}_{k} , {a}_{i} ) = Q ( {s}_{k} , {a}_{i} ) + {c}_{puct} \frac{π ( {s}_{k} , {a}_{i} )}{1 + N ( {s}_{k} , {a}_{i} )}$$

where the Q-score, Q(Sₖ, aᵢ), is computed as the average cumulative reward obtained after selecting aᵢ from state Sₖ throughout the search process, N(Sₖ, aᵢ) is the number of times a particular action is selected, π(Sₖ, aᵢ) is the predicted probability by the policy network, and c_{puct} is a hyperparameter controlling how much trust to place in the empirically computed reward across search and the trained policy network. In embodiments, alternative Upper Confidence Bound scores may be used.

Compared to greedy decoding, where the policy network only chooses the action with the highest probability, MCTS explores multiple probable actions to explore the search space more fully. Because policy network and forward model execution is fast, the overall inference time with MCTS is fast: 17.3 s per target response, and 0.135 s per MCTS iteration per target response. This computation time is obtained by running the models on a GPU Nvidia RTX3070 8 GB, and by loading data through a CPU Intel Core i7-11700KF. In embodiments, other combinations of GPU and/or CPUs may be used. Advanced search algorithms, such as MCTS, greatly improve inference performance in most reinforcement learning applications [20]-[22], including metamaterial generation. In embodiments, the present invention uses 128 MCTS iterations with C_{puct} set to 2.5. In embodiments, the present invention uses one or more of: 32, 64, or 256 iterations of MCTS, and/or c_{puct} set to 1-5, or 2-4. In embodiments, other combinations of parameters are used.

### Autoregressive Framework for Constrained Graph Generation

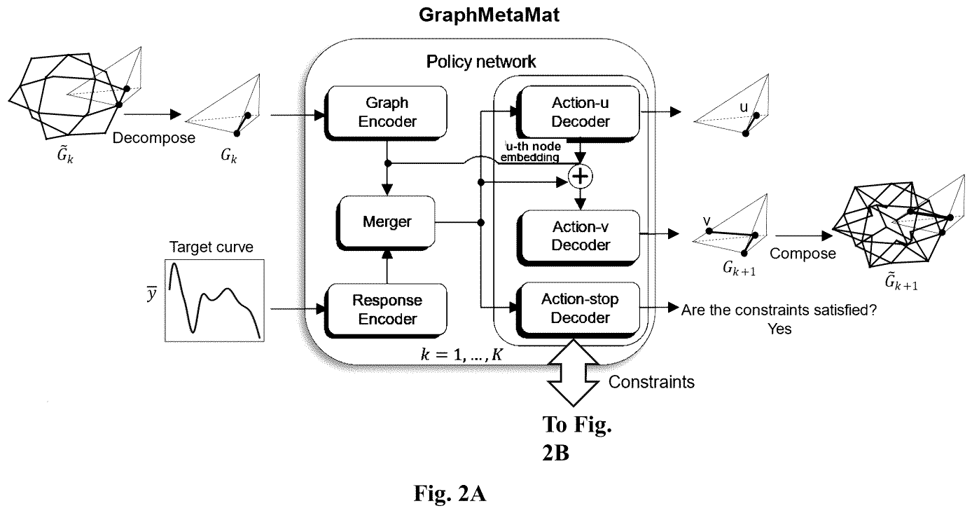

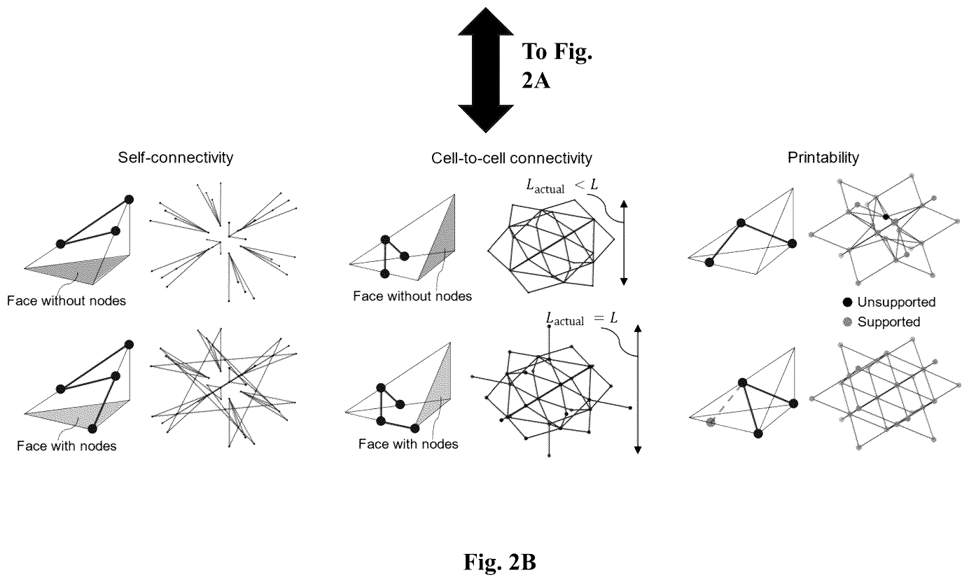

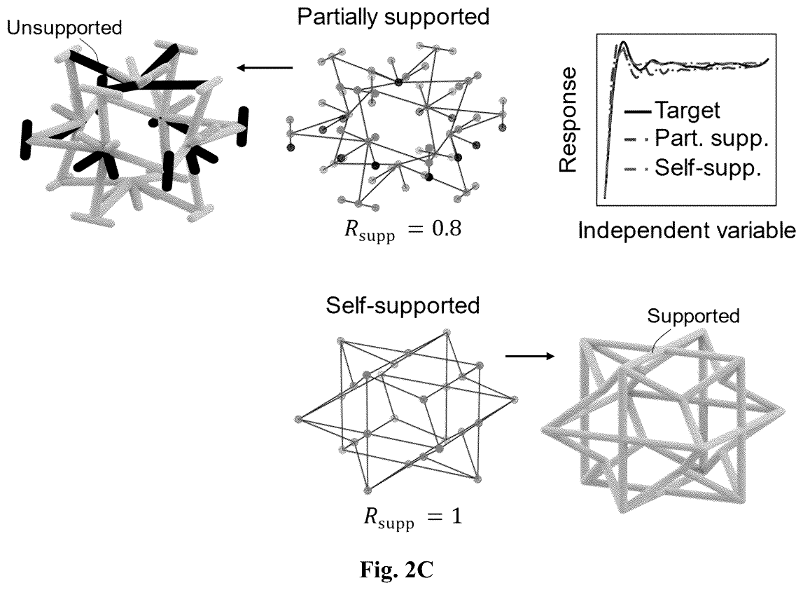

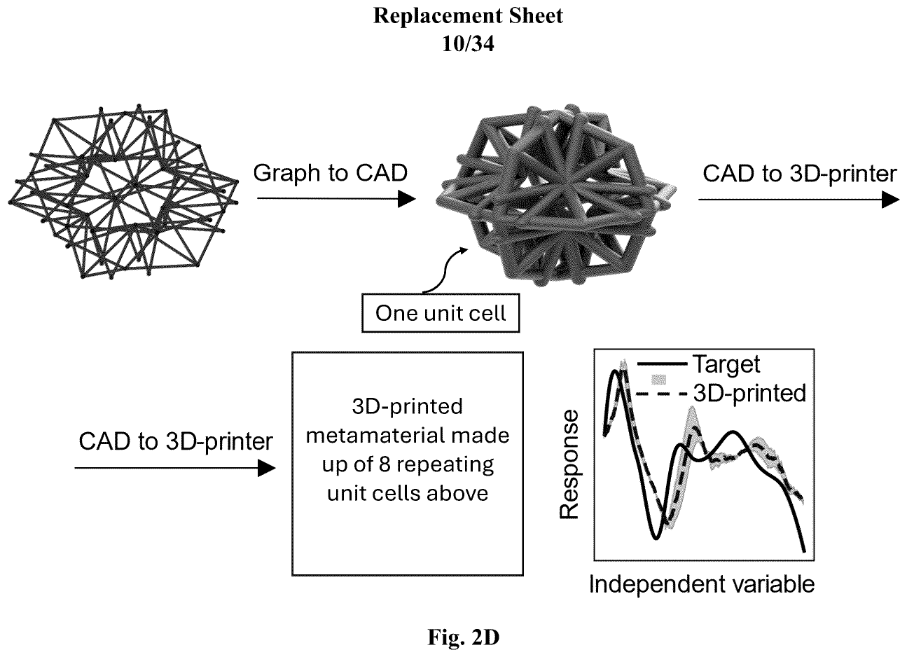

FIG. 2A depicts an autoregressive policy network used to generate graphical representations of metamaterial with target functional responses, in accordance with embodiments of the present invention. In embodiments, the autoregressive policy network includes one or more of the following: a graph encoder, a response encoder, a merger, an action-u decoder, and action-v decoder, an action-stop decoder.

In embodiments, at each step k=1, . . . , K, the SRV graph Gₖ and the target curve y̅ are input into a policy network model through a graph and response encoder, respectively. In embodiments, a portion of a graph larger than the SRV is input into the graph encoder. In embodiments, less than the full target curve y̅ is input into the response encoder. In embodiments, the policy network predicts the start node u and end node v to form a new edge, and the stop token S. In embodiments, when the generation stops (step K), the final SRV graph, G_{K} is transformed into the unit cell graph, \tilde{G}_{K+1}. In embodiments, during RL training, \tilde{G}_{K+1} is input into the forward model to predict the functional response, guiding the policy optimization.

FIG. 2B depicts geometric and manufacturing constraints that can be enforced in embodiment of the present invention. In embodiments, the constraints can include self-connectivity, cell-to-cell connectivity, and/or printability, to name a few examples.

In FIG. 2B, for each constraint (self-connectivity, cell-to-cell connectivity and printability), the top and bottom row show an example of missing and satisfied constraint, respectively. For example, for self-connectivity, if the horizontal face of the SRV does not have any nodes, although the SRV graph is a connected sequence of nodes, self-connectivity is not satisfied. For example, for cell-to-cell connectivity, if the vertical face of the SRV does not have any nodes, and L_{actual}<L although the SRV graph is a connected sequence of nodes, cell-to-cell-connectivity is not satisfied. For example, for printability, if a cell contains an unsupported node, then printability is not satisfied. In embodiments, additional constraints such as the maximum number of SRV graph nodes, Vₘₐₓ and the relative density, ρ̅ bounds can be constrained. In embodiments, other constraints may be applied.

FIG. 2C depicts examples of inverse designed unit cells with and without printability constraints corresponding to partially supported and self-supported in the figure, for a target stress-strain response curve, in accordance with embodiments of the present invention. Printability indicates whether a metamaterial can be 3D-printed without adding external supports. In the partially supported images the graph of the metamaterial, thinner lines, and the corresponding computer aided design (CAD) model, thicker lines, contain unsupported nodes, indicated by a darker color in the CAD model. This means that the printability constraint will be violated if imposed. Both of the self supported image and the corresponding CAD model are supported indicating printability is not violated. Rₛᵤₚₚ is the degree of support, i.e., the fraction of supported nodes. While achieving virtually identical response (FE-reconstructed curves in the plot), unlike the unconstrained design, the constrained structure is fully self-supported, i.e., it can be 3D-printed without adding external supports.

FIG. 2D depicts a generated unit cell graph, converted into a CAD model, tessellated periodically in space, 3D-printed using digital light stereolithography, and experimentally tested using universal testing machines or electrodynamical shakers along with laser vibrometers, in accordance with embodiments of the present invention. The image shows a 3D-printed sample for target transmission response. Scale bar, 10 mm.

Embodiments of an inverse-design framework are illustrated in FIGS. 2A-2C. In embodiments, to enforce geometric constraints during metamaterial generation, the design process in graph space is decomposed into an autoregressive Markov decision process, where edges are autoregressively added to the SRV graph, G (V, E), trained using RL. In embodiments, edges are autoregressively added one edge at a time. In embodiments, edges are autoregressively added two or more at a time.

In embodiments using a stop-token, at each generation step, the RL environment ensures that all desirable geometric properties or constraints are satisfied. In embodiments, the desirable geometric properties include maximum number of graph nodes, Vₘₐₓ, self-connectivity, and cell-to-cell connectivity, and functional responses, to name a few examples. Specifically, the generation process starts at an initial state s₀=(G₀, y̅), which consists of the empty graph G₀=(Ø, Ø), and the target response y̅. At each (pseudo-) time step k, the RL agent selects an action aₖ=((u, v), S), composed of an edge (u, v): u, v∈V, and a Boolean stop token S. If the stop token is true, the search process ends. Otherwise, the selected edge is added to the previous graph: Gₖ₊₁=(Vₖ∪{u, v}, Eₖ∪{(u, v)}). In embodiments, at each step k, the agent adds multiple edges at a time. When the search process ends, the resulting SRV graph is tessellated into the metamaterial's unit cell graph, \tilde{G}.

In embodiments, the RL agent is modeled with a policy network, π_{θ} (FIG. 2A), conditioned on a target curve, y̅. According to dataset generation in accordance with embodiments of the present invention, the possible node locations are discretized into 5 equidistant positions on each edge of the SRV. This introduces an action space of 22 possible locations across the SRV. In embodiments, the possible node locations are discretized into 3-7 equidistance positions on each edge of the SRV.

In embodiments, at each autoregressive step, the policy network first encodes the current state, sₖ=(Gₖ, y̅) by running a graph encoder on the SRV graph Gₖ, a curve encoder on the input response y̅, and merging them together with an MLP. In embodiments, the policy network then decodes the state embedding by running three different MLPs to select the start node u, the end node v, and the stop token S. While the goal of the agent at each step is to choose an edge in the SRV, due to efficiency reasons, in embodiments, the policy network predicts two nodes. To resemble picking an edge, the end node selection is conditioned on the start node by concatenating the end node MLP's input with the graph encoder embedding of the chosen start node.

In embodiments, the policy network is trained using a proximal policy optimization (PPO) scheme [45], aiming to maximize the future expected reward R. This ensures the generated metamaterial exhibits any desired response. In embodiments, the PPO is function of Jaccard, J which measures the similarity between the target response, y̅ and the generated metamaterial's response, y. PPO is an unsupervised learning algorithm, greatly reducing the data costs for conditioning on new desired responses. Hence, any new response can be encoded through training a new response encoder. RL requires repeated reward computations. In embodiments, a GNN-based forward, i.e., structure-to-response, model was trained to efficiently predict the response of the inverse-designed metamaterials. In embodiments, other types of forward models are used. In embodiments, one or more of pretraining and physics-bias are adopted to improve the forward model's generalizability. In embodiments, snapshot ensembles [46] are used to efficiently estimate prediction uncertainty. In embodiments, other models are used to compute reward computations, such as FE simulations, or analytical methods.

In embodiments, 16 evenly spaced relative densities between the upper and lower bound densities (constraint) are tested to pick the best performing p according to the reward. In embodiments, 0-20 spaced relative densities are tested. Testing relative density can have a large effect on the reward calculations.

In embodiments, the policy network is pretrained. In embodiments, the policy network is pretrained using a variety of methods, including imitation learning (IL) or semi-supervised learning, to name a few. In embodiments, the policy network is pretrained using IL to learn the correct sequence of actions, {a₀, . . . , aₖ} for graph-labeled training target curves. Pretraining using IL was shown to improve model performances.

In embodiments, inferring a graphical representation of a metamaterial based on a target physical property involves using a search algorithm, such as Monto Carlo Tree Search (MCTS), or greedy search to name a few. In embodiments using MCTS, the invention uses MCTS rollouts to estimate the value of each state sₖ in a search tree by sampling each action aₖ₊₁˜π_{θ}(·|sₖ) from its probability distribution over actions. In embodiments, the model iteratively samples multiple generated graphs and selects the best one from a set number of iterations, such as 32, 64, 128, 256, or 512 to name a few. This significantly improving inverse design performance. In embodiments, the corresponding structure is 3D-printed and tested (FIG. 2C).

As opposed to state-of-the-art inverse-design methods [28][36][37], embodiments of the present invention allows for flexible enforcement of geometric constraints (FIG. 2B). In embodiments, one of more of the following constraints are performed: symmetry is constrained by design through the SRV graph; the relative density into the arbitrary ranges 0.05-0.25 and 0.02-0.30; the maximum number of SRV graph nodes, Vₘₐₓ is limited to 4 to reduce data requirement and possible edge intersections; and all generated graphs are physically viable by enforcing self-connectivity, and cell-to-cell connectivity (FIG. 2B). These constraints are satisfied by masking possible actions. Depending on the design space, different constraints can be imposed in the present invention. In embodiments, the constrains include one or more of the following: symmetry, relative density, maximum number of nodes, self-connectivity, and cell-to-cell connectivity.

Manufacturing constraints can also be included. FIG. 2B (right panel) shows how the position of a single node in the SRV graph can determine printability, intended as in ref. [41]. Printability depends on the final graph rather than on the single predicted graph nodes. Therefore, to enforce printability on each action, all possible sequences of actions that enable printable structures must be known beforehand. While feasible in 2D, the extension to 3D graphs becomes intractable. To overcome this challenge and to make the solution more general, the present invention can employ an additional reward term, Rₛᵤₚₚ measuring the fraction of supported nodes, acting as a weak constraint. As a result, the generated structure, while still matching the target response, only needs a few additional or no supports at all (FIG. 2C) to be printable. Employing a Markov decision process guided by an autoregressive policy network thus enables to design truss metamaterials with arbitrary geometric constraints, pivotal in the ‘design for manufacturing’ of architected materials.

### EXAMPLES

Examples are provided below to facilitate a more complete understanding of the invention. The following examples illustrate the exemplary modes of making and practicing the invention. However, the scope of the invention is not limited to specific embodiments disclosed in these Examples, which are for purposes of illustration only.

In the examples that follow, an embodiment of the present invention was used, GraphMetaMat (GMM). This embodiment is a graph-based framework that uses a graph neural network (GNN) agent to perform autoregressive metamaterial generation. In this embodiment a ‘response-to-structure’ policy network is trained via deep imitation learning (IL) and reinforcement learning (RL), and combined with a ‘structure-to-response’ surrogate model and Monte Carlo tree search (MCTS) to inverse design truss metamaterials with prescribed nonlinear functional responses and arbitrary geometric constraints.

GMM encodes metamaterial designs into a graph space G (V, E). It uses a design space of cubic symmetric periodic truss metamaterials with cylindrical struts, decomposing cubic volumes into 48 tetrahedra. The struts' radius, rᵢⱼ is obtained from the relative density, ρ̅ sampled in the range 0.05-0.25, assuming a constant unit cell size, L. ˜3000 graph-curve data points were generated via high-fidelity FE simulations for quasi-static stress-strain and wave transmission responses. The constitutive material is modeled as linear elastic with Young's modulus Eₛ=4.0 MPa, and Poisson's ratio vₛ=0.3, with properties of the Formlabs Flexible 80A material.

To enforce geometric constraints during metamaterial generation, the design process in graph space is decomposed into an autoregressive Markov decision process, where edges are autoregressively added to the SRV graph, G (V, E), trained using RL. The RL agent selects one edge at a time to add to the graph. Stop tokens are used. The possible node locations were discretized into 5 equidistant positions on each edge of the SRV; an action space of 22 possible locations across the SRV.

The following constraints were applied to GMM. First, symmetry is constrained by design through the SRV graph. Second, the relative density was constrained into the arbitrary ranges 0.05-0.25 and 0.02-0.30. Third, the maximum number of SRV graph nodes, Vₘₐₓ is limited to 4 to reduce data requirement and possible edge intersections. Lastly, all generated graphs are physically viable by enforcing self-connectivity, and cell-to-cell connectivity.

### Example 1—Inverse Design of Unseen and User-Defined Nonlinear Stress-Strain Responses

Embodiments of the present invention can be evaluated on two classes of unseen compressive stress-strain and vibration transmission curves. To the first class belong curves with known associated structures yet unseen during training (test dataset), here defined as ‘known curve space’. User-defined responses, where the existence of an associated structure is not guaranteed, represent the second class of target curves, here defined as ‘unknown curve space’.

In Example 1, In Example 2, embodiments of the present invention were tested on unseen and user-defined non-linear stress-strain responses.

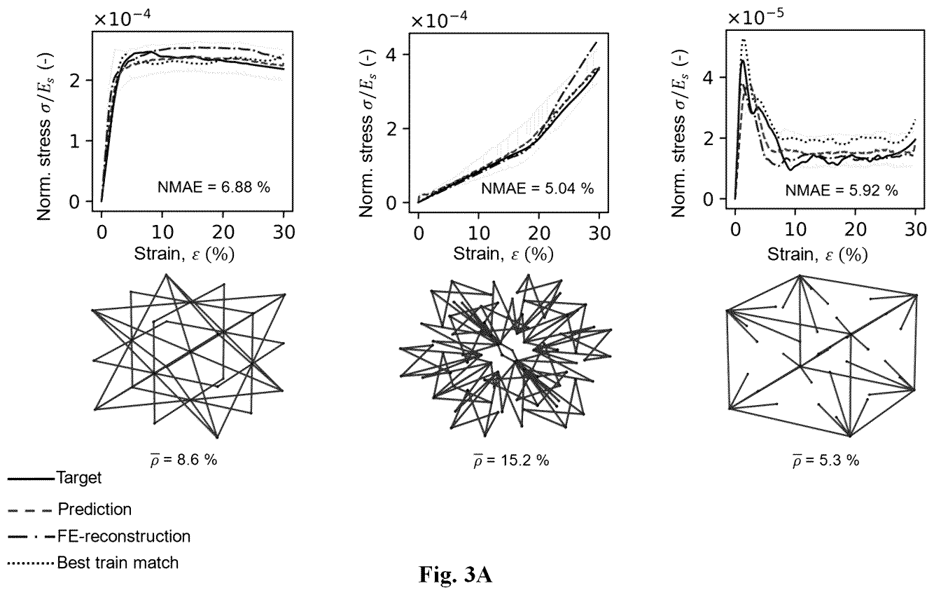

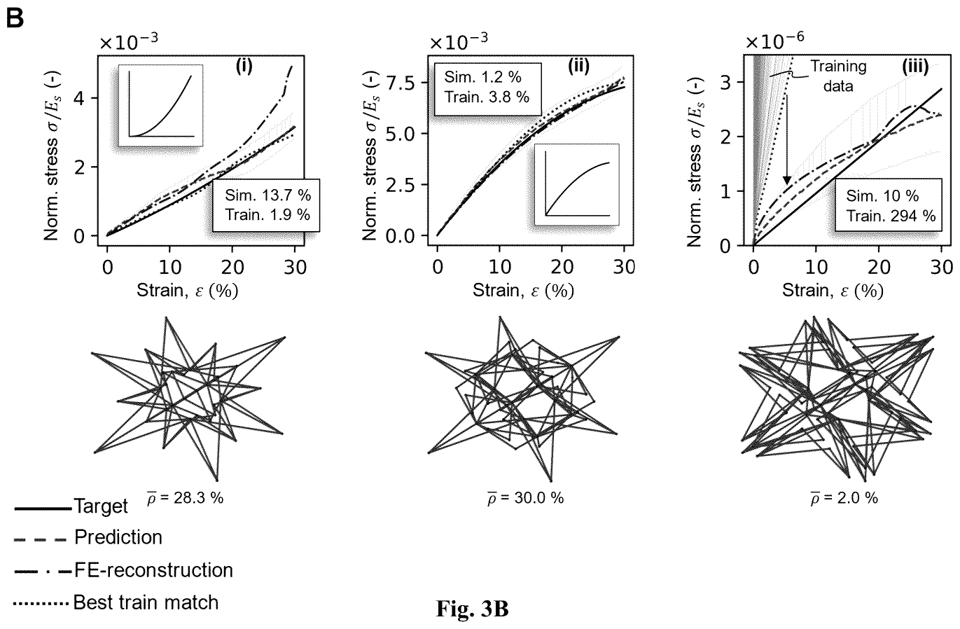

FIG. 3A depicts target curves sampled from the ‘known curve space’ (test dataset) in accordance with embodiments of the present invention. The normalized mean absolute error (NMAE) is used to evaluate performance. NMAE is objective and scale invariant. It is calculated as follows:

$$NMAE = \frac{\vert y - \overline{y} \vert}{{\overline{y}}_{max} - {\overline{y}}_{min}} \times 100 .$$

The NMAE values correspond to the rlative error between the target and the FE-reconstructed curves.

FIG. 3A depicts plots of the forward model predictions, the closest curve from the training dataset (best train match), and the FE-reconstructed responses of three generated designs for representative compressive target curves from the known curve space in FIG. 3A. The GMM model can capture strain-hardening due to self-contact, perfect-plasticity-like and softening due to buckling, with relative errors (NMAE) between the FE-reconstructed and target curves of 5-6%. These errors are close to the mismatch between the forward-predicted and target responses, proving GMM's ability to accurately inverse-design unseen targets.

FIG. 3B depicts target curves sampled from the ‘unknown curve space’ (user-defined targets). (i), (ii), and (iii) correspond to convex strain-hardening, concave strain-hardening, and soft target responses, respectively. Soft curves identify with linear curves with stiffness much lower than that of the softest structure in the dataset. Boxes report the NMAE values between the target and FE-reconstructed curves (‘Sim.’), and between the target and best train match curves (‘Train’). In all plots, the stress is normalized by the constitutive material's Young's modulus Eₛ.

Three types of targets are considered here: (i) convex strain hardening, (ii) concave strain hardening, and (iii) softer than the most compliant structure in the dataset. To help the model find possible designs, ρ̅ search was extended to the range 0.02-0.30. Interestingly, the model can capture the target curve's shape for (i) and (ii), with errors comparable to those of the best train match. While curves of type (i) and (ii) are from unknown curve space, their average stress falls into the training range. On the contrary, the average stress of curves of type (iii) is out-of-distribution. GMM thus exploits the extended ρ̅ range to design structures with much lower stress, outperforming the best train match by ˜30 times.

### Example 2—Inverse Design of Unseen and User-Defined Nonlinear Vibration Response

In Example 2, embodiments of the present invention were tested on unseen and user-defined non-linear vibration responses.

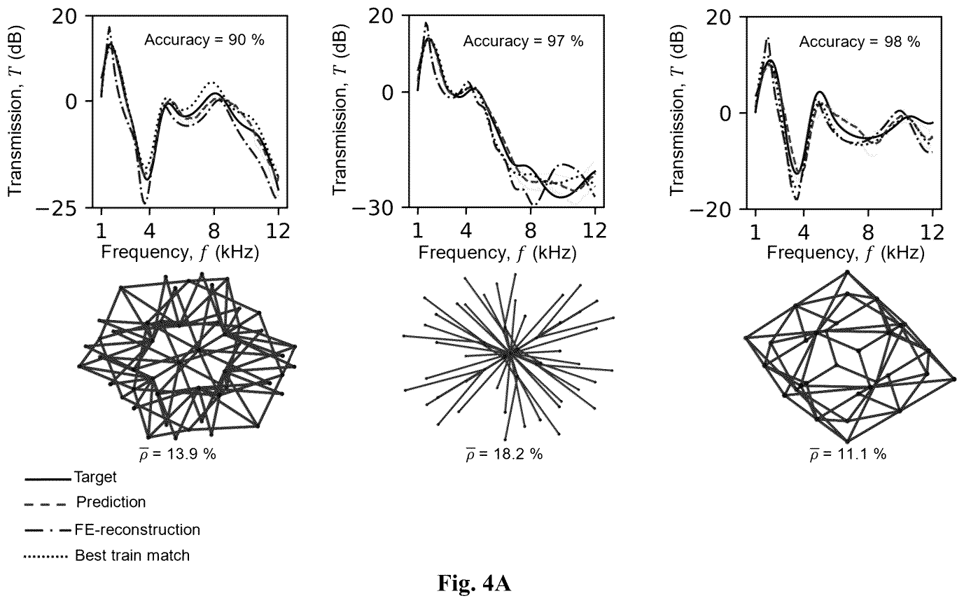

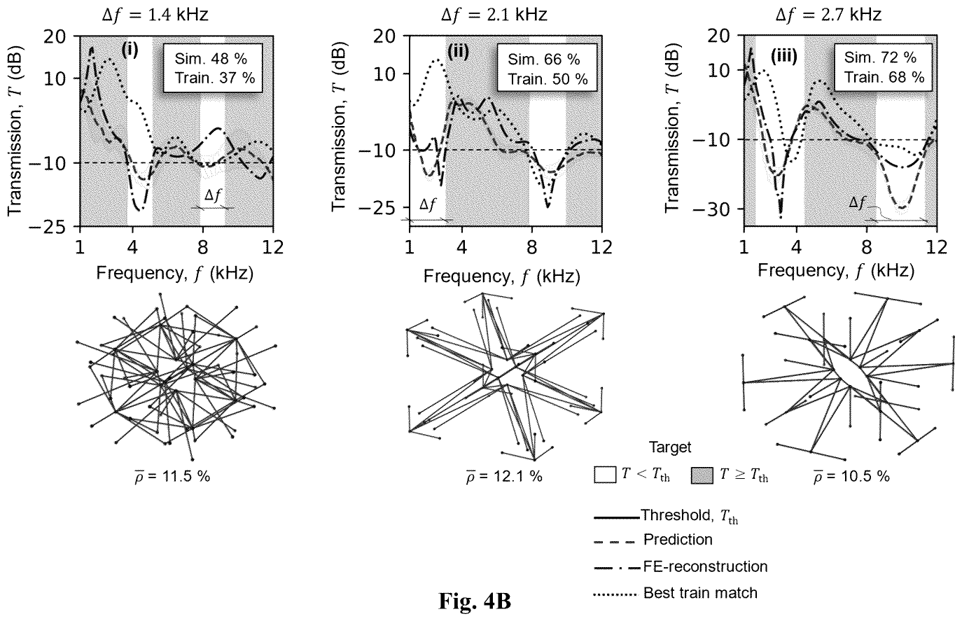

FIG. 4A depicts target curves sampled from the ‘known curve space’ (test dataset). The accuracy values are calculated between the target and the FE-reconstructed curves.

Similar to compressive response design shown in FIG. 3A, FIG. 4A shows a set of results for representative transmission target responses from the known curve space. By defining a transmission threshold, Tₜₕ=−10 dB, the computed accuracy of ˜95% between the FE-reconstructed and target curves for these examples, demonstrates the GMM model can design structures with unseen transmission curves.

FIG. 4B depicts target binary sequences sampled from the ‘unknown curve space’ (user-defined targets) in accordance with embodiments of the present invention. (i), (ii), and (iii) correspond to targets with two variable attenuation gaps of size Δf=1.4, 2.1, 2.7 kHz, respectively. The boxes report the accuracy values between the target and FE-reconstructed curves (‘Sim.’), and between the target and best train match curves (‘Train’). For all accuracy calculations, the transmission threshold Tₜₕ is set to −10 dB.

FIG. 4B shows the results on target curves from the unknown curve space. Defining realistic target transmission curves is far more challenging than shaping realistic stress-strain responses, and applications often require metamaterials with specific attenuation gaps (low transmission in certain frequency ranges) rather than exact transmission values. To this end, instead of targeting transmission curves T(f), the targets were set to binary sequences defined by thresholding T with Tₜₕ, where ‘0’ corresponds to ‘low transmission’ (T<Tₜₕ) and ‘1’ to ‘high transmission’ (T≥Tₜₕ). In embodiments used for this evaluation, during RL training, the forward model still predicts the transmission curve, which is then binarized for comparison with the target sequence. Three types of targets are defined, (i), (ii), and (iii), with varying gap size Δf, from ˜1.4 to 2.1 and 2.7 kHz, respectively. FIG. 4B highlights how embodiments of the present invention can design structures with out-of-distribution target attenuation gaps, with variable central frequencies and gap size, outperforming best train matches.

### Comparison With Other Methods

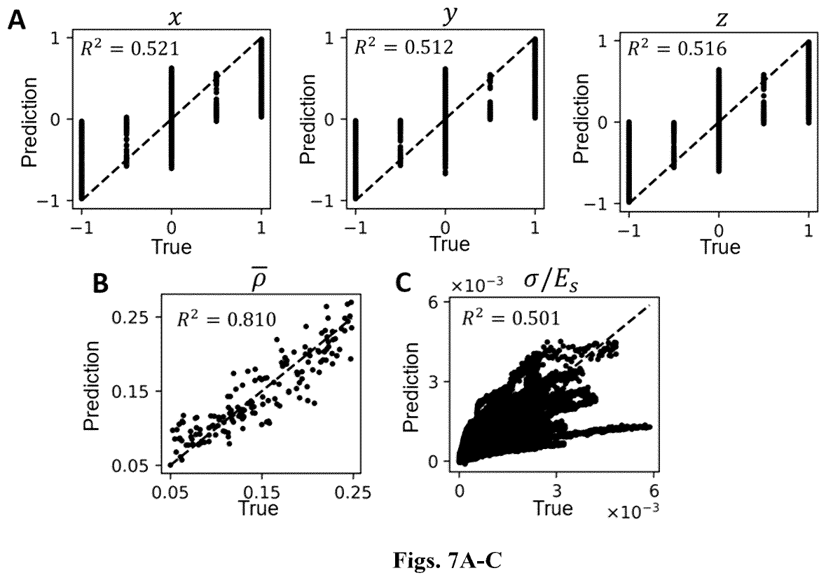

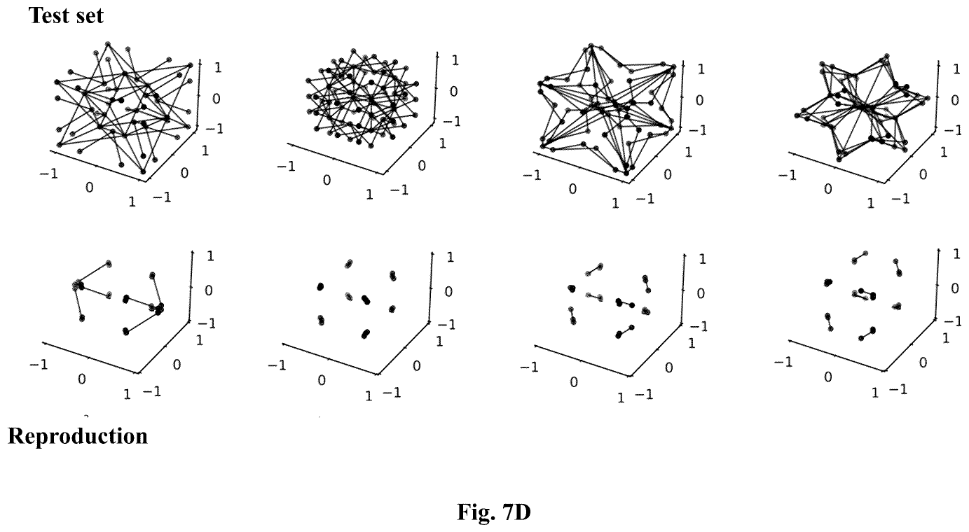

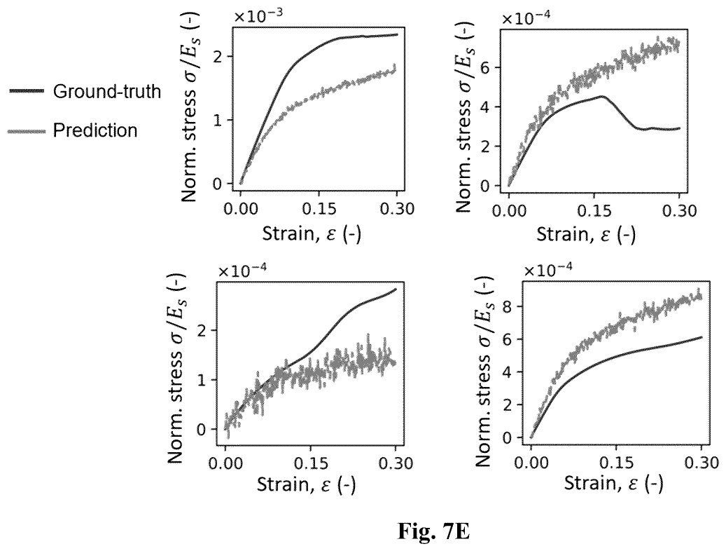

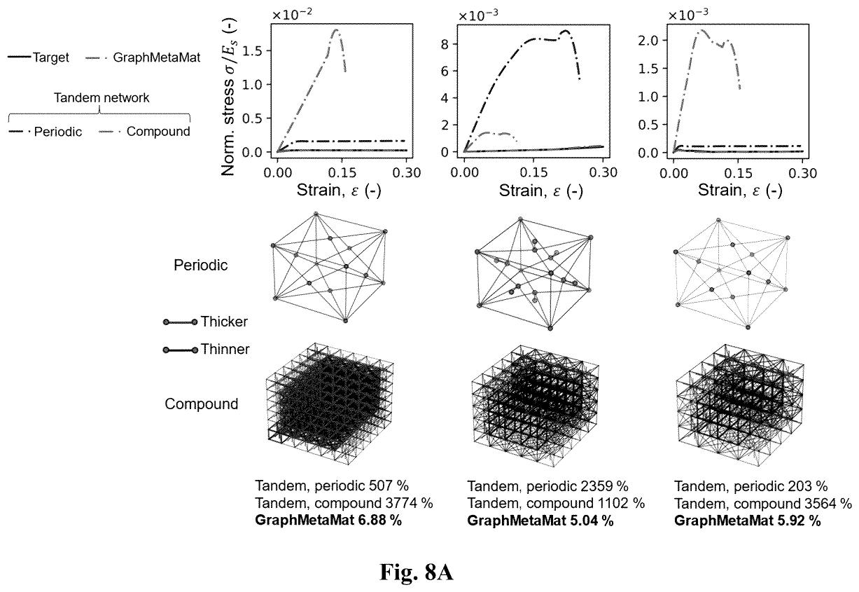

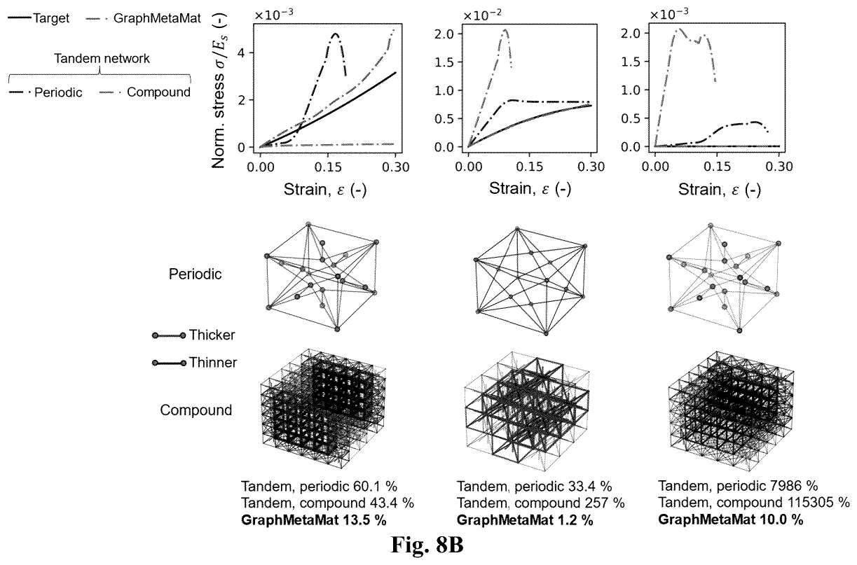

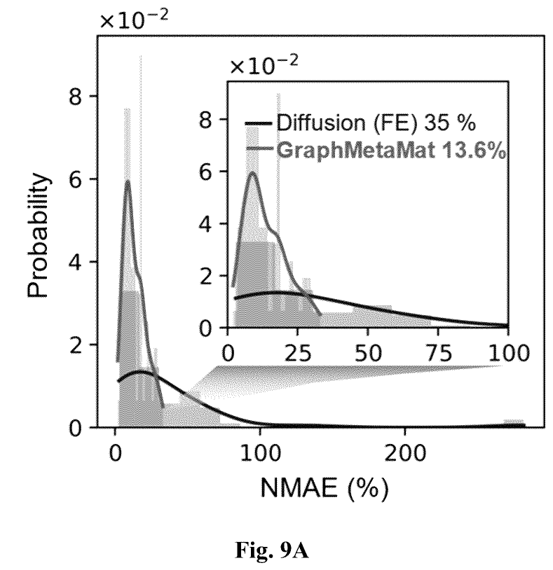

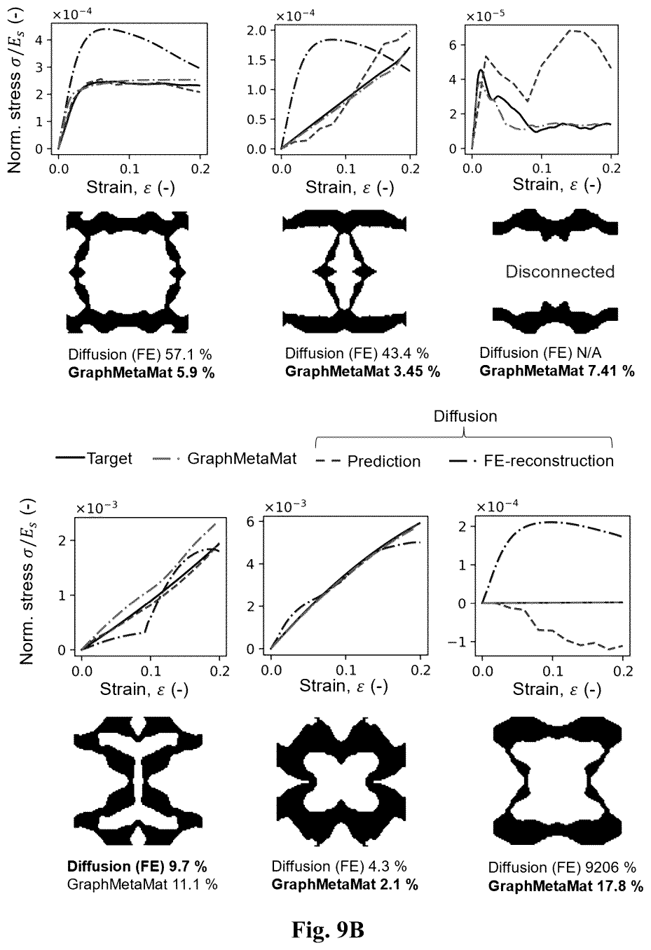

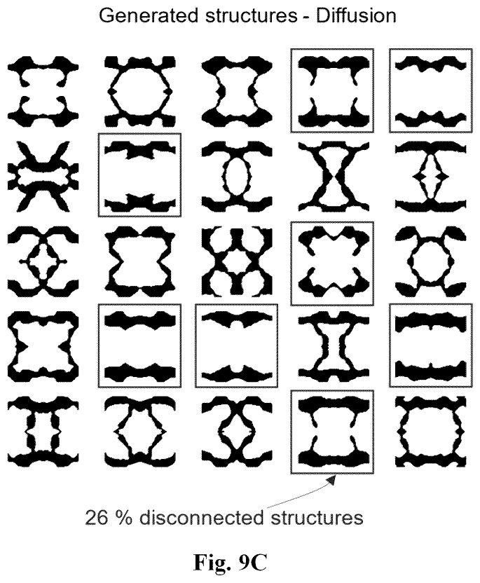

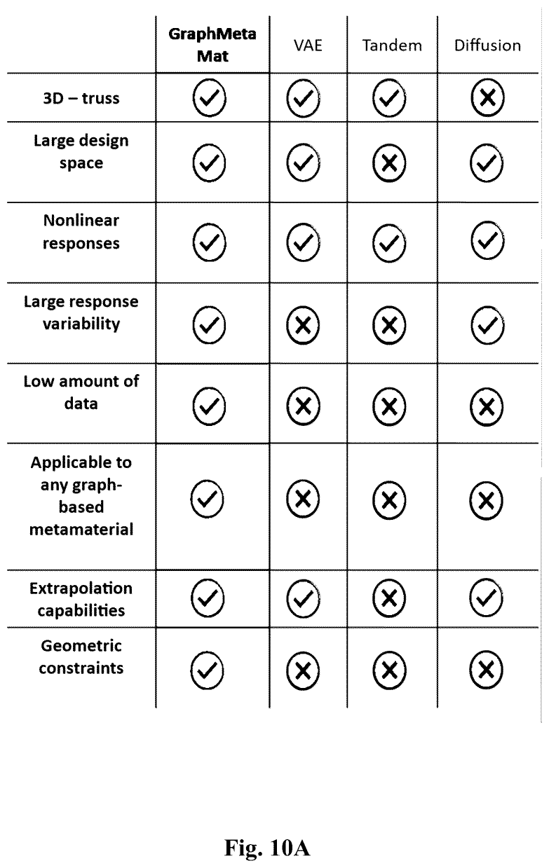

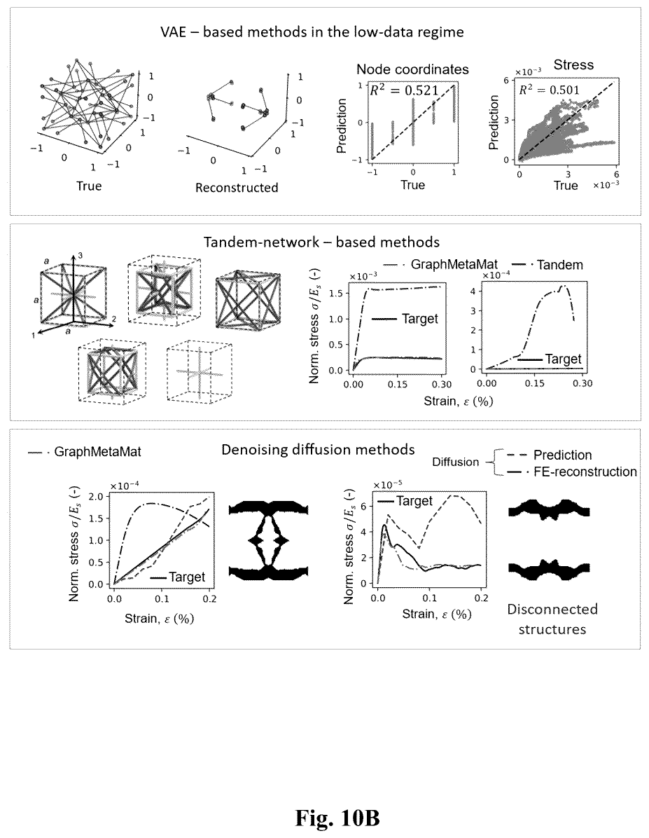

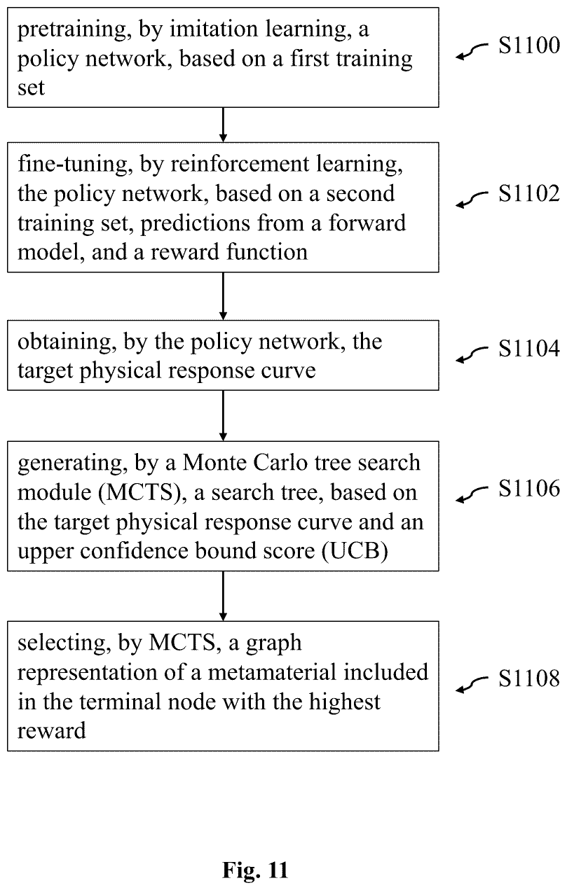

An in-depth comparison between GMM and state-of-the-art inverse-design methods [28][36][37] highlights the clear advantage of the present invention. MLP-based variational autoencoder methods [37] fail to reconstruct our graphs (FIGS. 7A-7E), a crucial step for enabling gradient-based inverse design, thus restricting their applicability to data-intensive problems. Limited by design vector parametrization, MLP-based tandem networks [36] are unable to inverse design both test and user-defined stress-strain curves, with errors ranging from 30 to 100,000% (FIGS. 8A-8B), even when compound (non-uniform) metamaterials are employed to expand the design space. Furthermore, when benchmarked against denoising diffusion generative models [28], which are designed for 2D pixel-based structures rather than 3D truss metamaterials, Embodiments of the present invention achieves an average performance improvement of 60%, with peaks reaching a tenfold increase (FIGS. 9A-9C). In contrast to embodiments of the present invention, these models struggle to accurately capture nonlinear curves across a wide response range and fail to ensure the generation of valid, connected, and manufacturable structures (FIGS. 10A-10B).

FIGS. FIGS. 7A-7E depict a performance evaluation of the variational autoencoder (VAE) generative model of ref. [37] based on a test set.

FIG. 7A depicts predicted vs. true graph node coordinates of the VAE generated metamaterials based on a test set in accordance with embodiments of the present invention.

FIG. 7B depicts predicted vs. true relative density of the VAE generated metamaterials based on a test set in accordance with embodiments of the present invention.

FIG. 7C depicts predicted vs. true normalized stress values of the VAE generated metamaterials based on a test set.

FIG. 7D depicts four randomly extracted test vs. VAE-reconstructed graphs.

FIG. 7E depicts predicted vs. true stress-strain curves of the corresponding structures in FIG. 7D. The predicted curves were computed with a forward model according to embodiments of the present invention. These results reveal that this VAE-based approach, when trained on a graph-curve dataset in accordance with embodiments of the present invention, is unable to accurately reconstruct graphs, making it unable to inverse design target responses according to embodiments of the present invention using gradient-based optimization.

FIGS. 8A-8B depicts benchmarking GraphMetaMat with the MLP-based tandem-network model of ref. [36] on the target curves in FIGS. 3A-3B. The FE-reconstructed responses of the GraphMetaMat-generated designs are also plotted. The periodic unit cells and compound structures are shown as graphs. The values reported underneath the structures correspond to the average relative error between the target and corresponding FE-reconstructed curve. A few simulations are interrupted due to numerical issues caused by either complex buckling instabilities or structure densification; in these cases, the relative error is computed up to the corresponding last strain value. y. These MLP-based tandem networks fail at inverse designing our target stress-strain responses, exhibiting errors ranging from 33 to 115,000%.

FIG. 8A depicts benchmarking GraphMetaMat with the MLP-based tandem-network model of ref. [36] on the target curves in FIG. 3A.

FIG. 8B depicts benchmarking GraphMetaMat with the MLP-based tandem-network model of ref. [36] on the target curves in FIG. 3B.

FIGS. 9A-C depict benchmarking GraphMetaMat with the video denoising diffusion model of ref. [28].

FIG. 9A depicts relative error distributions for stress-strain inverse design on the test dataset. The relative error, NMAE is computed between the target and the FE-reconstructed curves. The values reported in the legend are the mean values.

FIG. 9B depicts inference results on the target curves in FIGS. 3A-3B in accordance with embodiments of the present invention. The top and bottom three plots and structures correspond to FIGS. 3A and B, respectively.

FIG. 9C depicts diffusion-generated structures for the first 25 target test stress-strain curves. GraphMetaMat demonstrates an average performance improvement of 60%, with peak improvements reaching a tenfold increase.

FIG. 10 depicts benchmark summary between GraphMetaMat and state-of-the-art inverse-design methods, according to embodiments of the present invention. VAE-based method refers to ref. [37]. Tandem-network method refers to ref. [36]. Denoising diffusion method refers to ref. [28].

### Example 3—Generation if Metamaterials with Impact-Protection Functions

In Example 3, GMM was applied to design cushioning metamaterial for lacrosse chest protectors.

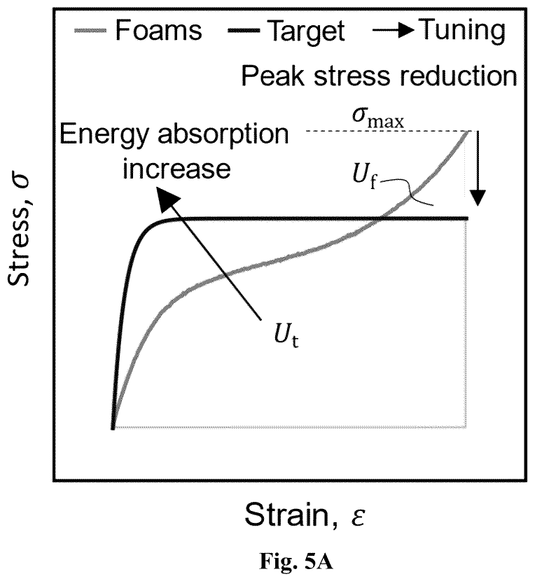

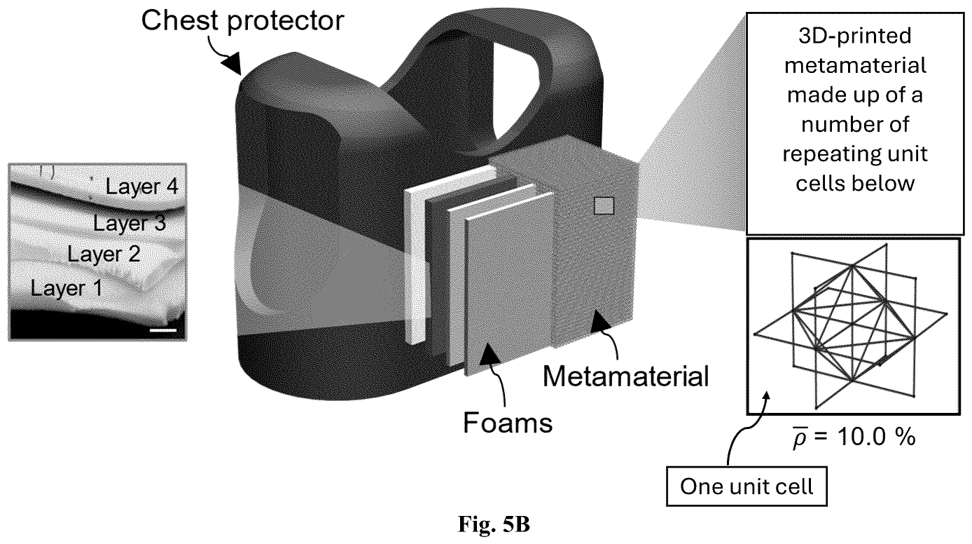

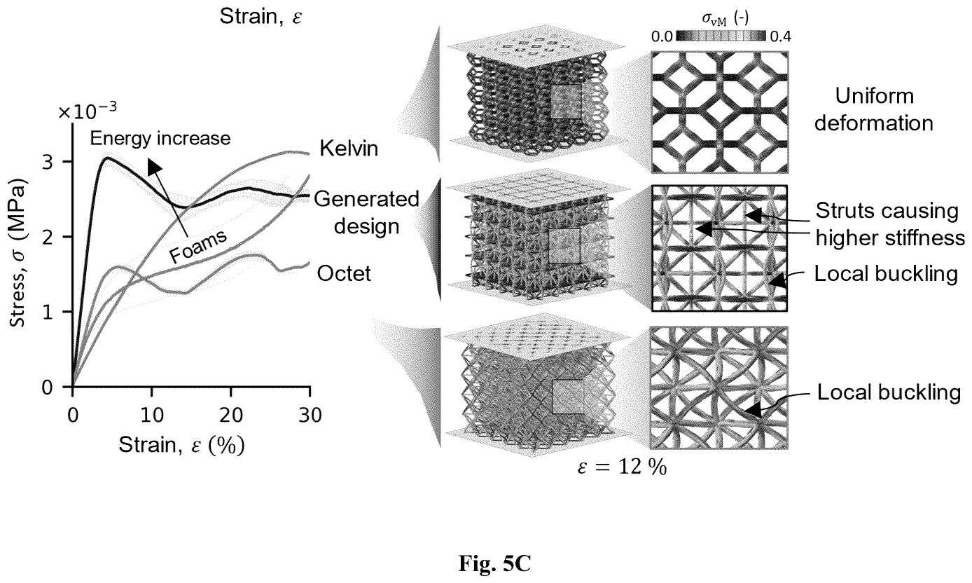

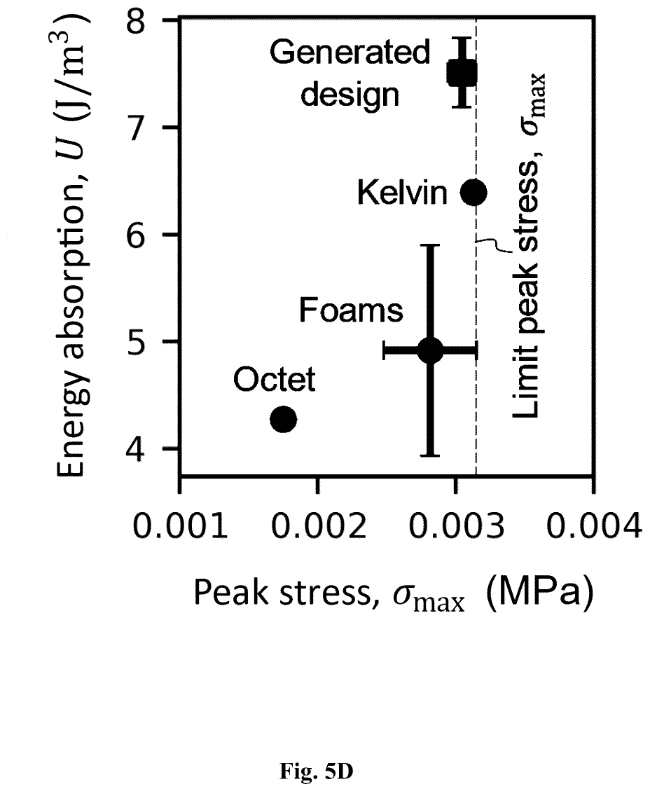

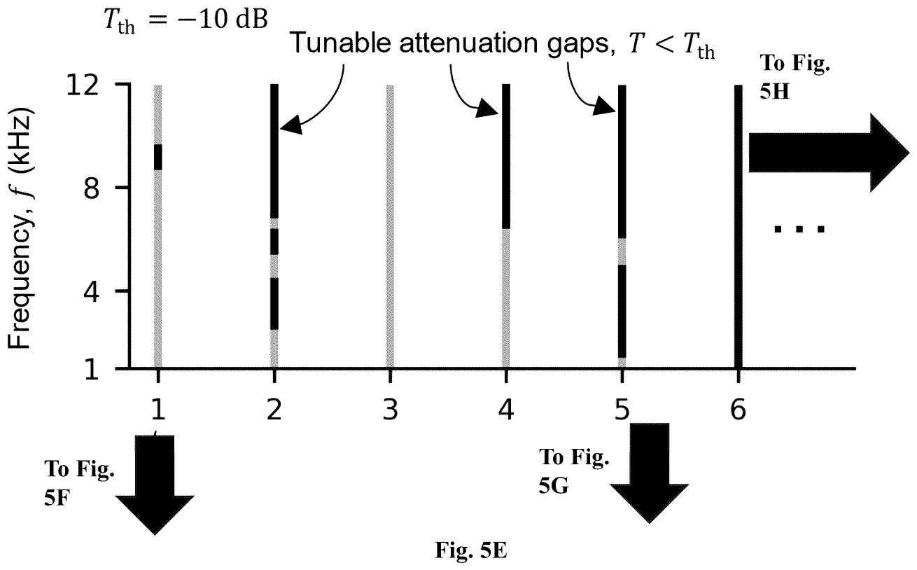

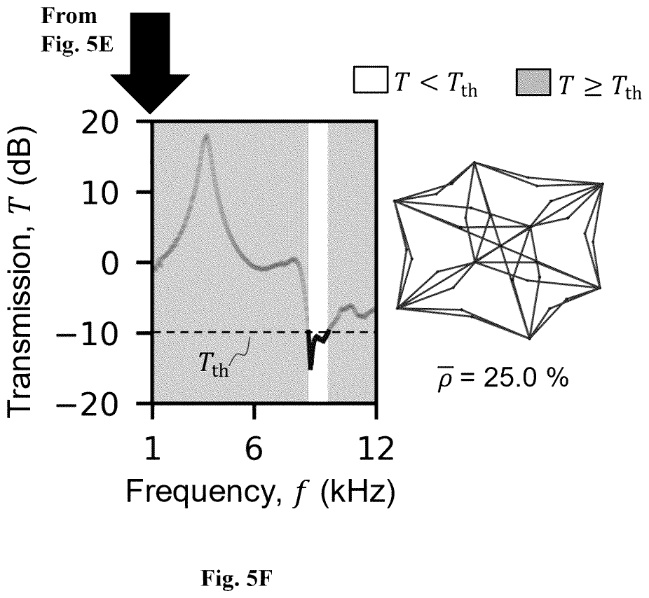

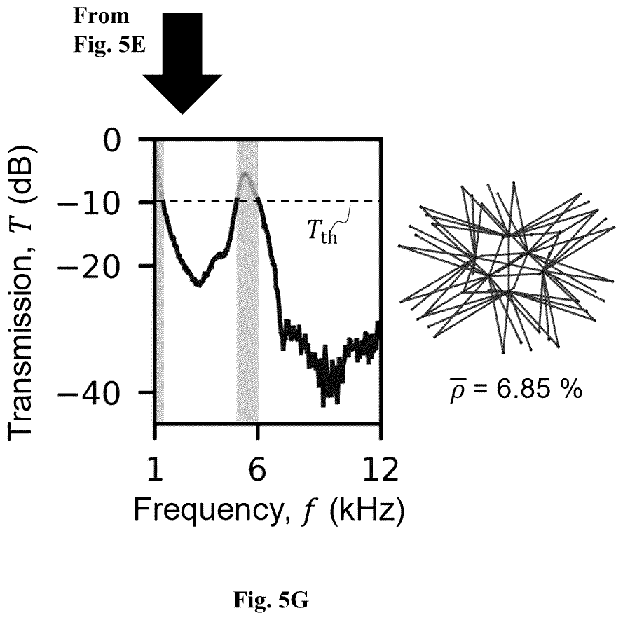

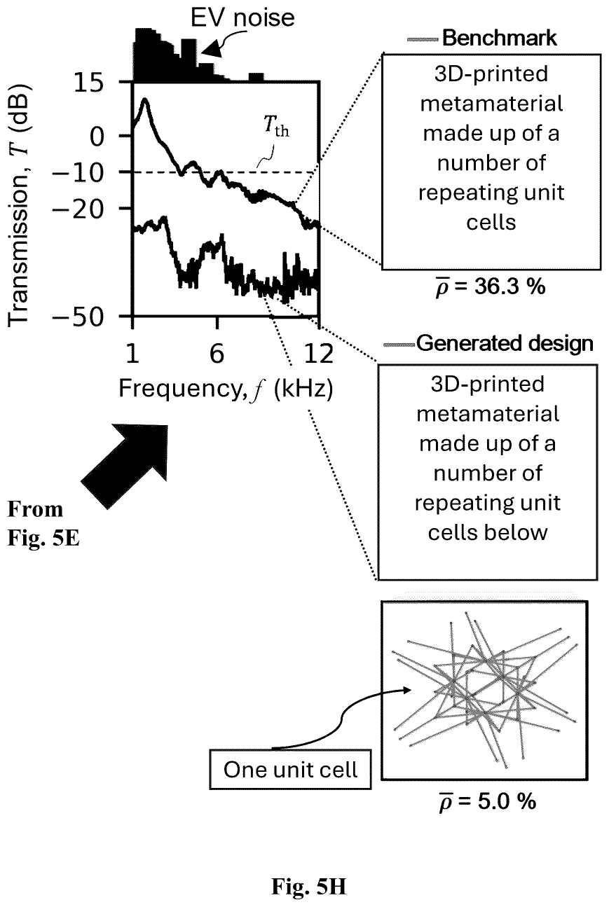

Chest protectors are usually composed of stacked foam layers (FIG. 5B), here referred to as ‘foams’, designed to overall reduce the transmitted peak force. GMM was used to explore the possibility to design a single-material 3D-printed periodic metamaterial able to outperform commercial foams. To this end, using the measured average compressive response of foams as baseline, stress-strain curves with lower or same peak stress, σₘₐₓ and higher energy absorption, U were targeted (FIGS. 5A-5B). To reduce the cost of high strain-rate training data collection, quasi-static responses with the model were first targeted (FIGS. 5A-5D) and verified the results with dynamic impact simulations. Restricting the design to ρ̅ between 5 and 10%, FIGS. 5B and 5C report an example of generated 3D-printed metamaterial with corresponding experimental stress-strain curve. The generated design was benchmarked with the baseline foams and two classical 3D periodic structures—Kelvin and octet. The performance summary in FIG. 5D indicates the generated design has a limited peak stress, close to that of Kelvin and commercial foams, yet ˜25-75% higher energy absorption, despite its apparent structural simplicity. The curves and FE-deformed shapes of the samples (FIG. 5C) demonstrate these results emerge from the interplay between higher stiffness, caused by struts aligned along the loading direction, increasing the energy absorption, and local buckling, limiting the peak stress.

FIG. 5A depicts a representative target stress-strain curve for cushioning application. The measured compressive response of stacked foam layers (identified as ‘Foams’) is used as baseline, with energy absorption, U_{f} and peak stress,

$${σ}_{max}^{f} .$$

The target response is designed to have higher energy absorption, Uₜ and lower peak stress,

$${σ}_{max}^{t} , i . e . , {U}_{t} \geq {U}_{f} and {σ}_{max}^{t} \leq {σ}_{max}^{f} .$$

The shaded areas identify the energy absorption, U.

FIG. 5B depicts schematic model of a chest protector, highlighting foams from a commercial lacrosse chest protector and the generated and 3D-printed metamaterial design in accordance with embodiments of the present invention. Scale bars, 10 mm.

FIG. 5C depicts an experimental stress-strain curves of the GMM generated design compared with those of the protector's foams (‘Foams’), Kelvin foam, and octet structure, in accordance with embodiments of the present invention. The generated design, Kelvin foam and octet structure were 3D-printed as 5×5×5 periodic tessellated samples with same relative density ρ̅=10%. The shaded areas correspond to the measurement variability, obtained with at least three samples per structure. The insets next to the curves show the 3D view and 2D zoom-in of the corresponding FE deformed shapes and von Mises stress distribution at ε=12%, highlighting the deformation mechanisms of the considered metamaterials.

FIG. 5D depicts a summary plot of energy absorption, U vs. peak stress, σₘₐₓ for all experiments in accordance with embodiments of the present invention. The error bars correspond to the measurement variability across different samples. Error bars for octet and Kelvin foam are not visible due to lower variability.

### Example 4—Generation of Metamaterials with Vibration-Attenuation Functions

In Example 4, GMM was applied to design vibration-damping panels for electric vehicles (EV).

Although electric motors are generally quieter than internal combustion engines, the pure tonal noise at frequencies above 1 kHz generated by electromagnetic forces is perceived as more annoying [47]. In the frequency range 1-12 kHz GMM can design structures with a large diversity of vibration attenuation gaps (FIG. 5E). By exploiting this capability, a broadband attenuation gap in the whole frequency range was targeted. FIG. 5H shows the 3D-printed designed metamaterial with broadband low transmission response, benchmarked with a state-of-the-art 3D-printed metamaterial optimized for broadband vibration filtering [48]. Two observations can be made. First, while the benchmark has an attenuation gap only for f>4 kHz, the generated design exhibits a broadband attenuation with transmission values below −20 dB at all frequencies. Second, the generated design is ˜86% lighter than the benchmark. In our dataset, lighter structures are correlated with low-transmission responses. This may explain why GraphMetaMat tends to favor lightweight designs for broadband attenuation gaps. Nevertheless, relative density alone does not guarantee full control over transmission response. The design of metamaterials with tunable transmission is indeed enabled by the simultaneous control of topology and relative density.

FIG. 5E depicts a frequency vs. design plot, highlighting GMM's ability to design a large diversity of tunable attenuation gaps in the frequency range 1-12 kHz, in accordance with embodiments of the present invention.

FIG. 5F depicts a generated unit cell graph along with the corresponding measured transmission response with small attenuation gap at higher frequencies, in accordance with embodiments of the present invention.

FIG. 5G depicts a generated unit cell graph along with the corresponding measured transmission response with two large attenuation gaps at lower and higher frequencies, in accordance with embodiments of the present invention.

FIG. 5H depicts a generated design with broadband attenuation gap in the whole frequency range, with potential applications to vibration-damping panels in EVs, in accordance with embodiments of the present invention. The plot shows the average measured transmission responses of the corresponding 3D-printed 2×2×2 samples of the generated design and the state-of-the-art locally resonant metamaterial [48]. Scale bar, 10 mm.

### DISCUSSION

Designing metamaterials with programmable functional responses addresses the need for customizable materials. The GMM framework, and other embodiments of the present invention, admits extension to any graph-representable metamaterials, including recently formulated shell-based structures [49], and functional responses, from thermal to optical and piezoelectric.

Compared to graph-based generative models, such as generative adversarial networks [50] and variational autoencoders [51], and prior inverse design frameworks [28][29][31][36][37][52], GMM offers several advantages: (1) via reinforcement learning, it explicitly imposes structural constraints, including self-connectivity, cell-to-cell connectivity, and manufacturability, ensuring valid designs; (2) owing to GNNs, it can handle any graph-based metamaterial, regardless of topology and size, and capture complex nonlinear physics; (3) it operates at inference time generating hundreds of valid structures with different target responses without costly gradient-based optimizations; (4) it controls both topology and relative density, resulting in a large design-response space. See for example FIGS. 10A-10B for summary benchmarks between GraphMetaMat and state-of-the-art methods.

The examples focused on the design of structures for single target responses, as compressive and vibrational curves. This enabled multi-objective optimizations of derived properties, like peak stress and energy absorption from stress-strain curves. GMM can also be extended to simultaneous design of multiple competing responses. For instance, simultaneously achieving structural support and broadband vibration filtering requires maximizing stiffness (slope of stress-strain curve) while reducing vibration transmission. Lastly, GMM offers a new platform extendable to the design of architected robotic matter [1][55], where geometric and manufacturing constraints pose extreme challenges for its industrial deployment.

Now that embodiments of the present invention have been shown and described in detail, various modifications and improvements thereon can become readily apparent to those skilled in the art. Accordingly, the exemplary embodiments of the present invention, as set forth above, are intended to be illustrative, not limiting. The spirit and scope of the present invention is to be construed broadly.

### REFERENCES

1. Cui, H. et al. Design and printing of proprioceptive three-dimensional architected robotic metamaterials. Science 376, 1287-1293 (2022).
2. Bauer, J. et al. Nanolattices: An Emerging Class of Mechanical Metamaterials. Advanced Materials 29, 1701850 (2017).
3. Filipov, E. T., Tachi, T. & Paulino, G. H. Origami tubes assembled into stiff, yet reconfigurable structures and metamaterials. Proc. Natl. Acad. Sci. U.S.A. 112, 12321-12326 (2015).
4. Portela, C. M. et al. Supersonic impact resilience of nanoarchitected carbon. Nat. Mater. 20, 1491-1497 (2021).
5. Schaedler, T. A. et al. Ultralight Metallic Microlattices. Science 334, 962-965 (2011).
6. Xia, X., Spadaccini, C. M. & Greer, J. R. Responsive materials architected in space and time. Nat Rev Mater 7, 683-701 (2022).
7. Ashby, M. F. The properties of foams and lattices. Phil. Trans. R. Soc. A. 364, 15-30 (2006).
8. Zheng, X. et al. Ultralight, ultrastiff mechanical metamaterials. Science 344, 1373-1377 (2014).
9. Meza, L. R., Das, S. & Greer, J. R. Strong, lightweight, and recoverable three-dimensional ceramic nanolattices. Science 345, 1322-1326 (2014).
10. Meier, T. et al. Obtaining auxetic and isotropic metamaterials in counterintuitive design spaces: an automated optimization approach and experimental characterization. npj Comput Mater 10, 3 (2024).
11. Xu, S., Shen, J., Zhou, S., Huang, X. & Xie, Y. M. Design of lattice structures with controlled anisotropy. Materials & Design 93, 443-447 (2016).
12. Cui, H. et al. Three-dimensional printing of piezoelectric materials with designed anisotropy and directional response. Nature Mater 18, 234-241 (2019).
13. Cheung, K. C. & Gershenfeld, N. Reversibly Assembled Cellular Composite Materials. Science 341, 1219-1221 (2013).
14. Gregg, C. E. et al. Ultralight, strong, and self-reprogrammable mechanical metamaterials. Sci. Robot. 9, eadi2746 (2024).
15. Woodman, S. J., Moore, A., Tagare, S., Cheung, K. & Kramer-Bottiglio, R. Deployable Cuboctahedrons for Adaptive Space Infrastructure. in 2024 IEEE 7th International Conference on Soft Robotics (RoboSoft) 75-81 (IEEE, San Diego, CA, USA, 2024). doi:10.1109/RoboSoft60065.2024.10521988.
16. Huang, Z., Panozzo, D. & Zorin, D. Optimized shock-protecting microstructures. Preprint at https://doi.org/10.48550/ARXIV.2310.08609 (2023).
17. Yang, D. et al. Buckling of Elastomeric Beams Enables Actuation of Soft Machines. Advanced Materials 27, 6323-6327 (2015).
18. Gerard, N. J. et al. Three-Dimensional Trampolinelike Behavior in an Ultralight Elastic Metamaterial. Phys. Rev. Applied 16, 024015 (2021).
19. Bastek, J.-H., Kumar, S., Telgen, B., Glaesener, R. N. & Kochmann, D. M. Inverting the structure-property map of truss metamaterials by deep learning. Proc. Natl. Acad. Sci. U.S.A. 119, e2111505119 (2022).
20. Kumar, S., Tan, S., Zheng, L. & Kochmann, D. M. Inverse-designed spinodoid metamaterials. npj Comput Mater 6, 73 (2020).
21. Li, B. et al. Computational discovery of microstructured composites with optimal stiffness-toughness trade-offs. Sci. Adv. 10, eadk4284 (2024).
22. Liu, H. et al. De Novo Atomistic Discovery of Disordered Mechanical Metamaterials by Machine Learning. Advanced Science 11, 2304834 (2024).
23. Luan, S., Chen, E., John, J. & Gaitanaros, S. A data-driven framework for structure-property correlation in ordered and disordered cellular metamaterials. Sci. Adv. 9, eadi1453 (2023).
24. Mao, Y., He, Q. & Zhao, X. Designing complex architectured materials with generative adversarial networks. Sci. Adv. 6, eaaz4169 (2020).
25. Shen, S. C. & Buehler, M. J. Nature-inspired architected materials using unsupervised deep learning. Commun Eng 1, 37 (2022).
26. Van'T Sant, S., Thakolkaran, P., Martínez, J. & Kumar, S. Inverse-designed growth-based cellular metamaterials. Mechanics of Materials 182, 104668 (2023).
27. Zheng, L., Kumar, S. & Kochmann, D. M. Data-driven topology optimization of spinodoid metamaterials with seamlessly tunable anisotropy. Computer Methods in Applied Mechanics and Engineering 383, 113894 (2021).
28. Bastek, J.-H. & Kochmann, D. M. Inverse design of nonlinear mechanical metamaterials via video denoising diffusion models. Nat Mach Intell 5, 1466-1475 (2023).
29. Maurizi, M., Gao, C. & Berto, F. Inverse design of truss lattice materials with superior buckling resistance. npj Comput Mater 8, 247 (2022).
30. Lew, A. J., Jin, K. & Buehler, M. J. Designing architected materials for mechanical compression via simulation, deep learning, and experimentation. npj Comput Mater 9, 80 (2023).
31. Thakolkaran, P., Espinal, M. A., Dhulipala, S., Kumar, S. & Portela, C. M. Experiment-informed finite-strain inverse design of spinodal metamaterials. Preprint at https://doi.org/10.48550/ARXIV.2312.11648 (2023).
32. Dold, D. & Aranguren Van Egmond, D. Differentiable graph-structured models for inverse design of lattice materials. Cell Reports Physical Science 4, 101586 (2023).
33. Zheng, X., Zhang, X., Chen, T. & Watanabe, I. Deep Learning in Mechanical Metamaterials: From Prediction and Generation to Inverse Design. Advanced Materials 35, 2302530 (2023).
34. Lee, D., Chen, W. (Wayne), Wang, L., Chan, Y. & Chen, W. Data-Driven Design for Metamaterials and Multiscale Systems: A Review. Advanced Materials 36, 2305254 (2024).
35. Yang, Y. et al. Guided Diffusion for Fast Inverse Design of Density-based Mechanical Metamaterials. Preprint at https://doi.org/10.48550/ARXIV.2401.13570 (2024).
36. Ha, C. S. et al. Rapid inverse design of metamaterials based on prescribed mechanical behavior through machine learning. Nat Commun 14, 5765 (2023).
37. Zheng, L., Karapiperis, K., Kumar, S. & Kochmann, D. M. Unifying the design space and optimizing linear and nonlinear truss metamaterials by generative modeling. Nat Commun 14, 7563 (2023).
38. Xu, K., Hu, W., Leskovec, J. & Jegelka, S. How Powerful are Graph Neural Networks? Preprint at https://doi.org/10.48550/ARXIV.1810.00826 (2018).
39. Lew, A. J. & Buehler, M. J. Single-shot forward and inverse hierarchical architected materials design for nonlinear mechanical properties using an Attention-Diffusion model. Materials Today 64, 10-20 (2023).
40. Liu, K., Sun, R. & Daraio, C. Growth rules for irregular architected materials with programmable properties. Science 377, 975-981 (2022).
41. Panetta, J. et al. Elastic textures for additive fabrication. ACM Trans. Graph. 34, 1-12 (2015).
42. Indurkar, P. P., Karlapati, S., Shaikeea, A. J. D. & Deshpande, V. S. Predicting deformation mechanisms in architected metamaterials using GNN. (2022) doi: 10.48550/ARXIV.2202.09427.
43. Makatura, L. et al. Procedural Metamaterials: A Unified Procedural Graph for Metamaterial Design. ACM Trans. Graph. 42, 1-19 (2023).
44. Maurizi, M., Gao, C. & Berto, F. Predicting stress, strain and deformation fields in materials and structures with graph neural networks. Sci Rep 12, 21834 (2022).
45. Schulman, J., Wolski, F., Dhariwal, P., Radford, A. & Klimov, O. Proximal Policy Optimization Algorithms. (2017) doi: 10.48550/ARXIV.1707.06347.
46. Huang, G. et al. Snapshot Ensembles: Train 1, get M for free. (2017) doi: 10.48550/ARXIV.1704.00109.
47. Meek, B., Van Der Auwear, H. & De Langhe, K. Challenges in NVH for Electric Vehicles. in Proceedings of the FISITA 2012 World Automotive Congress (eds. SAE-China & FISITA) vol. 191 675-685 (Springer Berlin Heidelberg, Berlin, Heidelberg, 2013).
48. Muhammad & Lim, C. W. Phononic metastructures with ultrawide low frequency three-dimensional bandgaps as broadband low frequency filter. Sci Rep 11, 7137 (2021).
49. Meyer, P. P., Bonatti, C., Tancogne-Dejean, T. & Mohr, D. Graph-based metamaterials: Deep learning of structure-property relations. Materials & Design 223, 111175 (2022).
50. Wang, H. et al. GraphGAN: Graph Representation Learning With Generative Adversarial Nets. AAAI 32, (2018).
51. Liu, Q., Allamanis, M., Brockschmidt, M. & Gaunt, A. L. Constrained Graph Variational Autoencoders for Molecule Design. Preprint at https://doi.org/10.48550/ARXIV.1805.09076 (2018).
52. Deng, B. et al. Inverse Design of Mechanical Metamaterials with Target Nonlinear Response via a Neural Accelerated Evolution Strategy. Advanced Materials 34, 2206238 (2022).
53. Yang, R., Sun, X. & Narasimhan, K. A Generalized Algorithm for Multi-Objective Reinforcement Learning and Policy Adaptation. Preprint at https://doi.org/10.48550/ARXIV.1908.08342 (2019).
54. Buterez, D., Janet, J. P., Kiddle, S. J., Oglic, D. & Lió, P. Transfer learning with graph neural networks for improved molecular property prediction in the multi-fidelity setting. Nat Commun 15, 1517 (2024).
55. Boley, J. W. et al. Shape-shifting structured lattices via multimaterial 4D printing. Proc. Natl. Acad. Sci. U.S.A. 116, 20856-20862 (2019).
56. Dorléans, V., Delille, R., Notta-Cuvier, D., Lauro, F. & Michau, E. Time-temperature superposition in viscoelasticity and viscoplasticity for thermoplastics. Polymer Testing 101, 107287 (2021).

What is claimed is:

1. A method for generating a metamaterial design based on a target physical response curve comprising a plurality of target physical response features including:
a) pretraining, by imitation learning, a policy network, based on a first training set, wherein:
i) the first training set includes:
1) a first plurality of graph representations of metamaterials, wherein each graph representation of a metamaterial includes nodes, edges, and graph connectivity; and
2) a first plurality of physical response curve features associated with the first plurality of graph representations of metamaterials;
ii) the policy network predicts a plurality of graph representations of metamaterials based on the first plurality of physical response curve features in the first training set;
b) fine-tuning, by reinforcement learning, the policy network, based on a second training set, predictions from a forward model, and a reward function, wherein:
i) the second training set includes a second plurality of physical response curve features;
ii) the policy network is configured to predict a second plurality of graph representations of metamaterials based on the second plurality of physical response curve features in the second training set;
iii) the forward model is configured to predict a third plurality of physical response curve features based on the second plurality of graph representations of metamaterials generated by the policy network;
iv) the reward function is configured to generate a first reward based on the second plurality of physical response curve features in the second training set and the third plurality of physical response curve features generated by the forward model; and
v) the fine-tuning continues until a predetermined first reward is met;
c) obtaining, by the policy network, the target physical response curve;
d) generating, by a Monte Carlo tree search module (MCTS), a search tree, based on the target physical response curve and an upper confidence bound score (UCB), wherein:
i) the search tree is comprised of:
1) a plurality of nodes, wherein each node of the search tree corresponds to a respective state sₖ, including a respective graph representation of a metamaterial and the target physical response curve;
2) a plurality of connections, wherein each connection is between a respective pair of nodes, and each connection corresponds to an action aᵢ representing the difference between the respective graph representations of the respective pair of nodes;
ii) the UCB is calculated for each connection in the plurality of connections based on:
1) a reward score Q, calculated using the reward function, based on an average cumulative reward for selecting the connection in the search tree;
2) a prediction, generated by the policy network, of the likelihood of selecting the connection from a plurality of connections connected to a first node in the pair of nodes, based on the target physical response curve; and
3) the number of times the connection is selected by MCTS;
iii) MCTS generates nodes based on connections that have a high UCB; and
iv) the reward function generates a reward for each terminal node based on the plurality of target physical response features, and the graph representation of a metamaterial included in each terminal node;
e) selecting, by MCTS, a graph representation of a metamaterial corresponding to the the terminal node with the highest reward.

2. The method of claim 1, wherein the target physical response curve comprises one or more of: a stress-strain response, an acoustic wave transmission response, a vibrational wave transmission response, or a photonic impedance profile.

3. The method of claim 1, wherein the target physical response curve comprises a stress-strain curve.

4. The method of claim 1, wherein the target physical response curve comprises a vibrational wave transmission response.

5. The method of claim 4, wherein the vibrational wave transmission response is an acoustic wave transmission response.

6. The method of claim 2, wherein the target physical response curve is non-linear.

7. The method of claim 1, wherein the policy network further comprises an action-stop decoder configured to accept one or more stop tokens.

8. The method of claim 7, wherein the one or more stop tokens corresponds to: self-connectivity, cell-to-cell connectivity, printability, a maximum number of graph nodes, a maximum number of graph nodes per smallest representable volume of a graph, and relative density of connections.

9. The method of claim 7, wherein a stop token corresponds to self-connectivity.

10. The method of claim 7, wherein a stop token corresponds to printability.

11. The method of claim 7, wherein a stop token corresponds to a maximum number of graph nodes.

12. The method of claim 7, wherein a stop token corresponds to a maximum number of graph nodes per smallest representable volume of a graph.

13. The method of claim 7, wherein a stop token corresponds to relative density of connections.

14. The method of claim 1, wherein the first plurality of graph representation of metamaterials and the first plurality of physical response features are each 10,000 or less, 5,000 or less, or 3,000 or less.

15. The method of claim 1, wherein the reward function is defined as: R=w_{J}J−w_{U}U, where J is a measure of the similarity between a target physical response y̅(x) and a metamaterial's physical response y(x), U is the uncertainty of the forward model, and w_{J} and w_{U} are two weighting hyperparameters.

16. The method of claim 1, wherein the UCB is calculated as follows:
$$score ( {s}_{k} , {a}_{i} ) = Q ( {s}_{k} , {a}_{i} ) + {c}_{puct} \frac{π ( {s}_{k} , {a}_{i} )}{1 + N ( {s}_{k} , {a}_{i} )}$$
where Q(sₖ, aᵢ), represents a reward score Q and is computed as the average cumulative reward obtained after selecting an action aᵢ from a state sₖ throughout the search tree, N(sₖ, aᵢ) is the number of times a particular action is selected, π(sₖ, aᵢ) is a predicted probability by the policy network, and c_{puct} is a hyperparameter.

17. The method of claim 16, wherein c_{puct} is set to 1-5, 2-3, or 2.5.

18. The method of claim 1, wherein the method further comprises printing by a 3D printer, or causing printing by a 3D printer, the metamaterial based on the graph representation.

19. A method for generating a metamaterial design based on a target physical response curve comprising a plurality of target physical response features including:
a) obtaining, by a policy network, the target physical response curve;
b) generating, by a Monte Carlo tree search module (MCTS), a search tree, based on the target physical response curve and an upper confidence bound score (UCB), wherein:
i) the search tree is comprised of:
1) a plurality of nodes, wherein each node of the search tree corresponds to a respective state sₖ, including a respective graph representation of a metamaterial and the target physical response curve;
2) a plurality of connections, wherein each connection is between a respective pair of nodes, and a connection corresponds to an action aᵢ representing the difference between the graph representations of the pair of nodes;
ii) the UCB is calculated for each connection in the plurality of connections based on:
1) a reward score Q, calculated using a reward function, based on an average cumulative reward for selecting the connection in the search tree;
2) a prediction, generated by the policy network, of the likelihood of selecting the connection from a plurality of connections connected to a first node in the pair of nodes, based on the target physical response curve; and
3) the number of times the connection is selected by MCTS;
iii) MCTS generates nodes based on connections that have a high UCB; and
iv) the reward function generates a reward for each terminal node based on the plurality of target physical response features, and the graph representation of a metamaterial included in each terminal node;
c) selecting, by MCTS, a graph representation of a metamaterial corresponding to the terminal node with the highest reward.

20. A computer system for generating a metamaterial design based on a target physical response curve comprising a plurality of target physical response features comprising one or more processors operably connected to one or more memories, the one or more memories containing computer-readable instructions, then when executed, cause the one or more processors to perform the method of:
a) pretraining, by imitation learning, a policy network, based on a first training set, wherein:
i) the first training set includes:
1) a first plurality of graph representations of metamaterials, wherein each graph representation of a metamaterial includes nodes, edges, and graph connectivity; and
2) a first plurality of physical response curve features associated with the first plurality of graph representations of metamaterials;
ii) the policy network predicts a plurality of graph representations of metamaterials based on the first plurality of physical response curve features in the first training set;
b) fine-tuning, by reinforcement learning, the policy network, based on a second training set, predictions from a forward model, and a reward function, wherein:
iii) the second training set includes a second plurality of physical response curve features;
iv) the policy network is configured to predict a second plurality of graph representations of metamaterials based on the second plurality of physical response curve features in the second training set;
v) the forward model is configured to predict a third plurality of physical response curve features based on the second plurality of graph representations of metamaterials generated by the policy network;
vi) the reward function is configured to generate a first reward based on the second plurality of physical response curve features in the second training set and the third plurality of physical response curve features generated by the forward model; and
vii) the fine-tuning continues until a predetermined first reward is met;
c) obtaining, by the policy network, the target physical response curve;
d) generating, by a Monte Carlo tree search module (MCTS), a search tree, based on the target physical response curve and an upper confidence bound score (UCB), wherein:
viii) the search tree is comprised of:
1) a plurality of nodes, wherein each node of the search tree corresponds to a respective state sₖ, including a respective graph representation of a metamaterial and the target physical response curve;
2) a plurality of connections, wherein each connection is between a respective pair of nodes, and each connection corresponds to an action aᵢ representing the difference between the respective graph representations of the respective pair of nodes;
ix) the UCB is calculated for each connection in the plurality of connections based on:
1) a reward score Q, calculated using the reward function, based on an average cumulative reward for selecting the connection in the search tree;
2) a prediction, generated by the policy network, of the likelihood of selecting the connection from a plurality of connections connected to a first node in the pair of nodes, based on the target physical response curve; and
3) the number of times the connection is selected by MCTS;
x) MCTS generates nodes based on connections that have a high UCB; and
xi) the reward function generates a reward for each terminal node based on the plurality of target physical response features, and the graph representation of a metamaterial included in each terminal node;
e) selecting, by MCTS, a graph representation of a metamaterial corresponding to the terminal node with the highest reward.
